(19) United States
(12) Patent Application Publication
(10) Pub. No.: US 2025/0309152 A1
(43) Pub. Date: Oct. 2, 2025

(54) INDUCTOR, CORE SUBSTRATE, AND INTERPOSER

(71) Applicant: NGK INSULATORS, LTD., Nagoya-shi (JP)

(72) Inventors: Makoto TANI, Inazawa-shi (JP); Takashi EBIGASE, Nagoya-shi (JP); Takahiro ANDO, Nagoya-shi (JP); Asami NODA, Handa-shi (JP)

(21) Appl. No.: 19/234,346

(22) Filed: Jun. 11, 2025

Related U.S. Application Data
(63) Continuation of application No. PCT/JP2022/046233, filed on Dec. 15, 2022.

(51) Int. Cl. H01L 23/64; H01L 21/48; H01L 23/498; H10D 1/20

(52) U.S. Cl. CPC H01L 23/645; H01L 21/486; H01L 23/49827; H01L 23/49838; H10D 1/20

(57) ABSTRACT

An inductor includes a conductor portion and a magnetic substance portion. The conductor portion is made of a sintered material containing sintered metal. The magnetic substance portion is made of ceramics, and includes a plurality of magnetic substance segments disposed at different positions in one direction. Each of the magnetic substance segments is penetrated by the conductor portion and inorganically bonded to the conductor portion. The plurality of magnetic substance segments include at least one first magnetic substance segment and at least one second magnetic substance segment. The at least one first magnetic substance segment is made of a first magnetic material with a permeability having a peak at a first frequency. The at least one second magnetic substance segment is made of a second magnetic material with a permeability having a peak at a second frequency different from the first frequency.

### CROSS-REFERENCE TO RELATED APPLICATION

This application is a continuation application of PCT/JP2022/046233, filed on Dec. 15, 2022, the content of which is hereby incorporated by reference into this application.

### BACKGROUND

### Technical Field

The present invention relates to an inductor, a core substrate, and an interposer, and in particular to an inductor, a core substrate, and an interposer each of which includes a conductor portion made of a sintered material containing sintered metal and includes a magnetic substance portion made of ceramics.

### Description of the Background Art

According to Japanese Patent Application Laid-Open No. 2019-179792, an interposer is disposed between a semiconductor element and a motherboard in a semiconductor device. The interposer is connected to each of the semiconductor element and the motherboard through solder balls. A multilayer wiring printed board is used as the interposer. The interposer includes a core substrate, three conductor circuit layers stacked on the core substrate to face the semiconductor element, and three conductor circuit layers stacked on the core substrate to face the motherboard. A wiring dimension is reduced in stages by passing through the three conductor circuit layers of the interposer on which the semiconductor element is mounted.

Efficient power management is sometimes required for semiconductor elements for integrated circuits (ICs), for example. Voltage regulators typically control supply voltages to a plurality of computing cores included in a processor chip (a semiconductor element) according to, for example, an amount of computation of a processor. Each of the voltage regulators normally needs to include a switch, a capacitor, and an inductor. To control the supply voltage for each of the computing cores, the computing core needs to include a switch, a capacitor, and an inductor. In particular, the inductors are difficult to be built in the semiconductor element, and thus are prepared separately from the semiconductor element in normal cases. Use of a magnetic substance has been proposed to ensure a sufficient inductance while suppressing a footprint for the inductors.

US Patent Application Publication No. 2019/0279806 discloses a package substrate (a kind of an interposer herein) disposed between a die (a semiconductor element) and a board (a motherboard). An inductor for the aforementioned purpose is built in this package substrate. Specifically, the package substrate includes a substrate core, a conductive through hole penetrating the substrate core, and a magnetic sheath around the conductive through hole. The magnetic sheath may include magnetic particles. The substrate core may be any substrate on which build-up layers (conductor circuit layers) are formed. An organic material is exemplified as a material for the core substrate.

WO2007/129526 discloses a core substrate including an inductor. A method of manufacturing this inductor includes forming a through hole in an axial direction of a longitudinally extending magnetic substance, and forming a conductor on an inner surface of this through hole by metal plating. Forming a hollow in the conductor releases a stress caused by a difference in thermal expansion between the conductor and the magnetic substance. A method for embedding an inductor in the substrate includes forming a through hole in the substrate, inserting the inductor into the through hole, and filling a space between the inductor and the substrate with a resin.

WO2022/162888 discloses a core substrate with a built-in inductor for constructing an interposer on which a semiconductor element is to be mounted. The core substrate includes a ceramic substrate with through holes, conductor portions extending through the through holes and made of sintered metal, and magnetic substance portions surrounding the conductor portions within the through holes and made of ceramics.

A plurality of computing cores have recently been mounted on a die (a semiconductor element) to be bonded to an interposer. In particular, high-performance processors such as those for data servers each include many computing cores to increase computational processing capability. Thus, the number of computing cores per die area is large, and the die area per computing core is small. To address this, a high-density inductor having a higher inductance per unit area of an interposer has been sought.

US Patent Application Publication No. 2019/0279806 described above exemplifies that the conductive through hole (a conductor portion) and the magnetic sheath (a magnetic substance portion) formed around the conductor portion and including the magnetic particles are formed in the substrate core mainly made of an organic material. In this case, the magnetic substance portion needs to be formed at or below a heat resistant temperature of the organic material for the substrate core. Typical techniques satisfying this requirement include a technique of solidifying a resin in which magnetic particles are dispersed. When the magnetic substance portion includes the magnetic particles dispersed in the resin, however, limitation of a filling factor of the magnetic particles (a proportion of the magnetic particles per volume) makes it difficult to ensure a high permeability. While the size of each inductor to be built in the interposer needs to be reduced in response to the aforementioned densification of the interposer, the reduced dimensions of the inductor for the densification make it difficult to ensure a sufficient inductance because there is difficulty in increasing the permeability of the magnetic substance portion as described above.

In WO2007/129526 described above, the conductor (conductor portion) of the inductor includes a plating film. In other words, plating is used as a method for forming the conductor portion. Here, components of the magnetic substance of the inductor are likely to enter the conductor portion of the inductor in a plating solution. As a result, electrical characteristics (in particular, conductivity) of the conductor portion of the inductor greatly vary. Application of this inductor to an interposer thus tends to increase variations in electrical characteristics (in particular, conductivity) of the interposer.

In contrast, the aforementioned technology disclosed in WO2022/162888 facilitates suppressing variations in electrical characteristics of the conductor portions more than that using a plating film, because the conductor portions according to the technology are made of the sintered metal. Moreover, since the magnetic substance portions are made of ceramics, this technology facilitates increasing the permeability of the magnetic substance portions more than that of magnetic substance portions using a resin in which magnetic particles are dispersed.

Inductors normally have acceptable limits of thickness. Under such a constraint, applying a magnetic material with a high permeability to an inductor is conceivable to further increase an inductance of the inductor per unit area. This is because the inductance is approximately proportional to the permeability. However, simply prioritizing such a material selection creates a concern about excessive frequency dependence of the inductance.

### SUMMARY

The present invention has been conceived to solve the aforementioned problems, and has an object of providing an inductor, a core substrate, and an interposer which can suppress the frequency dependence of the inductance while maintaining the sufficient inductance.

Aspect 1 is an inductor including: a conductor portion made of a sintered material containing sintered metal; and a magnetic substance portion made of ceramics and including a plurality of magnetic substance segments disposed at different positions in one direction, each of the plurality of magnetic substance segments being penetrated by the conductor portion and inorganically bonded to the conductor portion, the plurality of magnetic substance segments including: at least one first magnetic substance segment made of a first magnetic material with a permeability having a peak at a first frequency; and at least one second magnetic substance segment made of a second magnetic material with a permeability having a peak at a second frequency different from the first frequency.

Aspect 2 is the inductor according to Aspect 1, wherein the at least one first magnetic substance segment and the at least one second magnetic substance segment are separated by a non-magnetic material in the one direction.

Aspect 3 is the inductor according to Aspect 1 or Aspect 2, wherein each of the at least one first magnetic substance segment and the at least one second magnetic substance segment comprises one magnetic substance segment.

Aspect 4 is the inductor according to Aspect 1 or Aspect 2, wherein the at least one first magnetic substance segment comprises two magnetic substance segments separated by the at least one second magnetic substance segment.

Aspect 5 is a core substrate that includes the inductor according to any one of Aspect 1 to Aspect 4; and an insulator substrate with a through hole in which the inductor is disposed.

Aspect 6 is an interposer on which a semiconductor element is mounted, the interposer including: the core substrate according to claim 5; and a wiring layer stacked on the core substrate.

According to Aspect 1, the at least one first magnetic substance segment is made of the first magnetic material with the permeability having a peak at the first frequency; and the at least one second magnetic substance segment is made of the second magnetic material with the permeability having a peak at the second frequency different from the first frequency. This suppresses the influence of each of the peaks on the frequency dependence of the inductance without significantly sacrificing the permeability. The frequency dependence of the inductance can thus be suppressed while maintaining the sufficient inductance.

These and other objects, features, aspects, and advantages of the present invention will become more apparent from the following detailed description when taken in conjunction with the accompanying drawings.

### BRIEF DESCRIPTION OF DRAWINGS

FIG. 1 is a cross-sectional view schematically illustrating a structure of electronic equipment;

FIG. 2 is a cross-sectional view illustrating electronic equipment according to a modification of FIG. 1;

FIG. 3 is a schematic diagram illustrating a structure of inductors built in a core substrate;

FIG. 4 is a circuit diagram illustrating an example electrical connection between a first inductor and a second inductor illustrated in FIG. 3;

FIG. 5 is a diagram schematically illustrating a structure of the core substrate in Embodiment 1, and is a partial cross-sectional view taken along the line V-V of FIG. 6;

FIG. 6 is a partial cross-sectional view taken along the line VI-VI of FIG. 5;

FIG. 7 is a graph exemplifying frequency dependences of relative permeabilities of the first to third magnetic materials;

FIG. 8 is a graph exemplifying the frequency dependences of permeabilities of the first to third magnetic materials and an effective permeability of a magnetic substance portion using a combination of the first to third magnetic materials where the permeabilities are normalized by values at a low frequency;

FIG. 9 is a partial cross-sectional view schematically illustrating one step of a method of manufacturing the core substrate in Embodiment 1;

FIG. 10 is a partial cross-sectional view schematically illustrating one step of the method of manufacturing the core substrate in Embodiment 1;

FIG. 11 is a partial cross-sectional view schematically illustrating one step of the method of manufacturing the core substrate in Embodiment 1;

FIG. 12 is a partial cross-sectional view schematically illustrating one step of the method of manufacturing the core substrate in Embodiment 1;

FIG. 13 is a partial cross-sectional view schematically illustrating one step of the method of manufacturing the core substrate in Embodiment 1;

FIG. 14 is a partial cross-sectional view schematically illustrating one step of the method of manufacturing the core substrate in Embodiment 1;

FIG. 15 is a partial cross-sectional view schematically illustrating one step of the method of manufacturing the core substrate in Embodiment 1;

FIG. 16 is a partial cross-sectional view schematically illustrating one step of the method of manufacturing the core substrate in Embodiment 1;

FIG. 17 is a partial cross-sectional view schematically illustrating one step of the method of manufacturing the core substrate in Embodiment 1;

FIG. 18 is a partial cross-sectional view schematically illustrating a structure of a core substrate in Embodiment 2;

FIG. 19 is a partial cross-sectional view schematically illustrating one step of a method of manufacturing the core substrate in Embodiment 2;

FIG. 20 is a partial cross-sectional view schematically illustrating one step of the method of manufacturing the core substrate in Embodiment 2;

FIG. 21 is a partial cross-sectional view schematically illustrating one step of the method of manufacturing the core substrate in Embodiment 2;

FIG. 22 schematically illustrates a structure of a core substrate in Embodiment 3;

FIG. 23 is a partial cross-sectional view schematically illustrating a structure of a core substrate in Embodiment 4;

FIG. 24 is a partial enlarged view of FIG. 23;

FIG. 25 is a perspective view of FIG. 24;

FIG. 26 illustrates a modification of FIG. 24;

FIG. 27 is a perspective view of FIG. 26;

FIG. 28 is a partial cross-sectional view schematically illustrating a structure of a core substrate in Embodiment 5;

FIG. 29 is a partial enlarged view of FIG. 28;

FIG. 30 is a partial perspective view of FIG. 29;

FIG. 31 is a partial cross-sectional view schematically illustrating a structure of an interposer in Embodiment 6;

FIG. 32 is a partial cross-sectional view schematically illustrating a structure of a core substrate included in the interposer in FIG. 31;

FIG. 33 is a cross-sectional view schematically illustrating a structure of an inductor chip included in the core substrate in FIG. 32;

FIG. 34 is a perspective view schematically illustrating a structure of the inductor chip in FIG. 33;

FIG. 35 is a partial perspective view schematically illustrating one step of a method of manufacturing the inductor chip in Embodiment 6;

FIG. 36 is a partial perspective view schematically illustrating one step of the method of manufacturing the inductor chip in Embodiment 6;

FIG. 37 is a partial perspective view schematically illustrating one step of the method of manufacturing the inductor chip in Embodiment 6;

FIG. 38 is a partial perspective view schematically illustrating one step of the method of manufacturing the inductor chip in Embodiment 6;

FIG. 39 is a partial perspective view schematically illustrating one step of the method of manufacturing the inductor chip in Embodiment 6;

FIG. 40 is a cross-sectional view schematically illustrating one step of the method of manufacturing the inductor chip in Embodiment 6; and

FIG. 41 is a partial perspective view schematically illustrating one step of the method of manufacturing the inductor chip in Embodiment 6.

### DESCRIPTION OF THE PREFERRED EMBODIMENTS

Embodiments of the present invention will be described below based on the drawings.

### Preliminary Description

First, technology that can be combined with each of the following Embodiments will be described below.

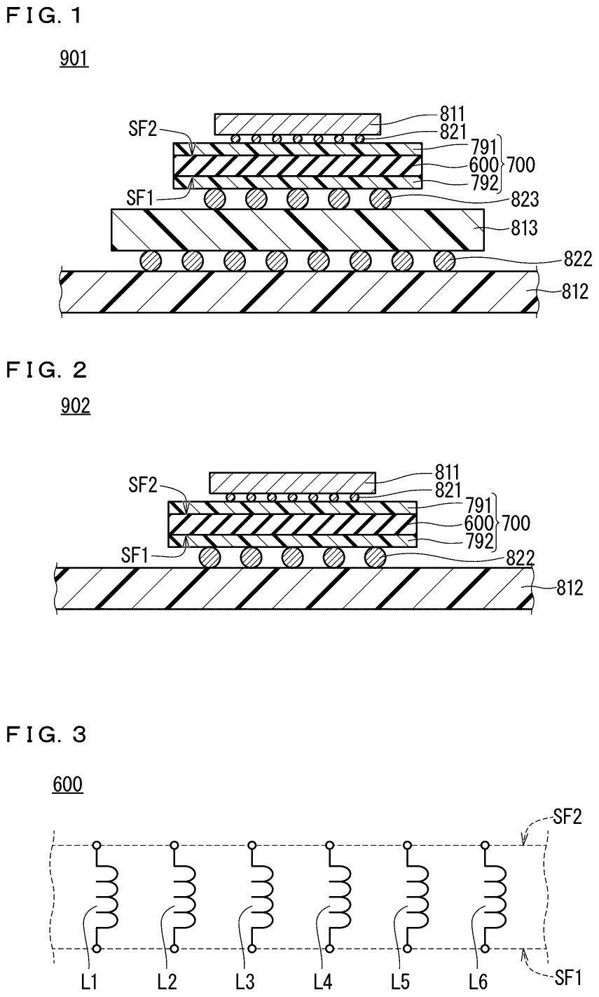

FIG. 1 is a cross-sectional view schematically illustrating a structure of electronic equipment 901. The electronic equipment 901 includes an interposer 700, a semiconductor element (a die) 811, a motherboard 812, and a package substrate 813. The interposer 700 includes a core substrate 600, a wiring layer 791, and a wiring layer 792. Any of core substrates 601 to 606 to be described in Embodiments below can be used as this core substrate 600.

The wiring layer 792 and the wiring layer 791 are stacked on one surface and the other surface (specifically, directly or indirectly on a first surface SF1 and a second surface SF2, respectively, to be described below) of the core substrate 600. The wiring layer 791 and the wiring layer 792 may be stacked on the core substrate 600 by build-up or sputtering, or may be bonded as separate wiring boards.

The wiring layer 791 is preferably a multilayer wiring layer configured to have a wiring dimension (e.g., a line and space (L/S) dimension) reduced from a side facing the core substrate 600 to a side facing the semiconductor element 811. The interposer 700 on which the semiconductor element 811 having a small terminal pitch can be mounted can thereby be constructed even if a wiring (L/S) dimension of the core substrate 600 is not so fine. Specifically, the wiring layer 791 may be a stack of a normal wiring layer facing the core substrate 600 and a fine wiring layer facing the semiconductor element 811.

The normal wiring layer may be formed by providing a wiring structure to a plate-like organic material component (e.g., an epoxy-based component) or an inorganic material component (e.g., a low temperature co-fired ceramic (LTCC) component or a non-magnetic ferrite component). Cu plating is used to form the wiring structure in the organic material component, for example. To form the wiring structure in the inorganic material component, the wiring structure is formed by firing Ag (silver), AgPd (silver palladium), or Cu (copper) simultaneously in forming the inorganic material component in a firing step. The fine wiring layer is preferably formed by providing a wiring structure to a plate-like organic material component (e.g., an epoxy-based or a polyimide-based component) in terms of ease of formation of fine wiring. Cu plating is used to form the wiring structure in the organic material component, for example.

The semiconductor element 811 is mounted on the wiring layer 791 of the interposer 700. The semiconductor element 811 is connected to the wiring layer 791 of the interposer 700 through solder balls 821, for example. The semiconductor element 811 may be an integrated circuit (IC) chip. In particular, when the IC chip is a processor chip including a plurality of computing cores, the aforementioned voltage regulator can be constructed using an inductor to be described below.

The interposer 700 is mounted on the package substrate 813 by bonding the wiring layer 792 to the package substrate 813. The wiring layer 792 is bonded to the package substrate 813 through, for example, solder balls 823. The package substrate 813 is mounted on the motherboard 812 by bonding these through, for example, solder balls 822.

According to the foregoing, an element side (a side facing the semiconductor element 811) of the interposer 700 is the wiring layer 791, and a substrate side (a side facing the package substrate 813 and the motherboard 812) of the interposer 700 is the wiring layer 792. A plurality of terminals (not illustrated) are disposed on each of the element side and the substrate side of the interposer 700. A terminal pitch on the element side may be smaller than a terminal pitch on the substrate side. Here, the interposer 700 has a function of changing the terminal pitch. As a modification, either or both of the wiring layer 791 and the wiring layer 792 may be omitted in some applications of the interposer.

FIG. 2 is a cross-sectional view illustrating electronic equipment 902 according to a modification of the electronic equipment 901 (FIG. 1). In the electronic equipment 902, the interposer 700 is bonded to the motherboard 812, for example, through the solder balls 822 without the package substrate 813 (FIG. 1) between them.

FIG. 3 is a schematic diagram illustrating a structure of inductors built in the core substrate 600. In the core substrate 600, a plurality of inductors L1 and L2 are built, additional inductors L3 to L6 may be built, and the number of inductors is any. While a structure of the inductors L1 and L2 will be described in detail below, for example, the inductors L3 to L6 may have the same structure.

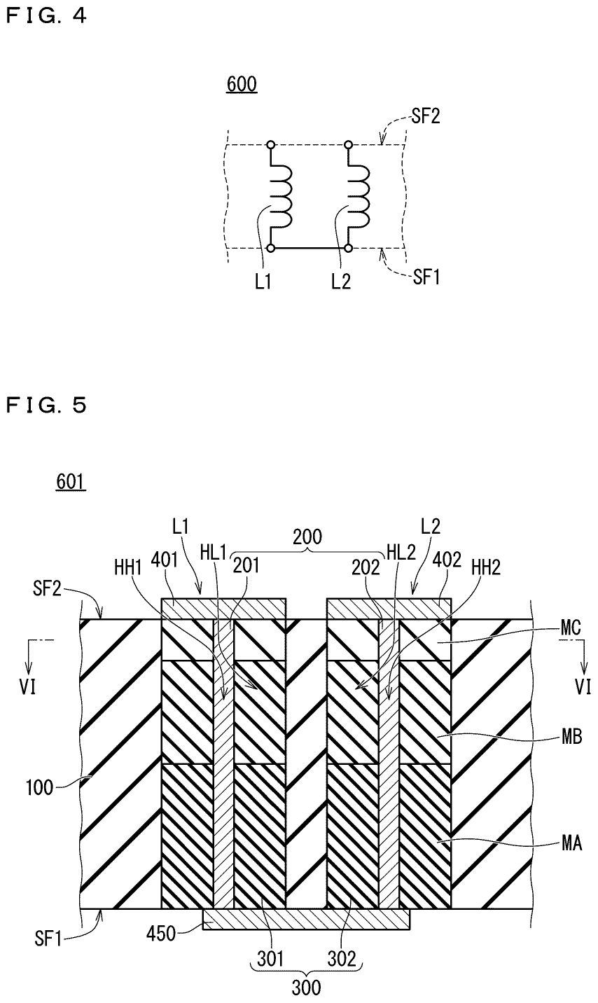

FIG. 4 is a circuit diagram illustrating an example electrical connection between the inductors L1 and L2 illustrated in FIG. 3. In this example, a series connection between the inductor L1 and the inductor L2 composes an inductor having a combined inductance larger than an inductance of each of the inductors L1 and L2, and both ends of the inductor are arranged on the second surface SF2 to face the semiconductor element 811 (FIG. 1). The inductor having a sufficiently large inductance can thereby easily be connected to the semiconductor element 811. Electrical connection between the plurality of inductors built in the core substrate is not limited to that illustrated in FIG. 4, and may be designed as appropriate according to the application of the core substrate. A series structure of any number of inductors, a parallel structure of any number of inductors, or a combination of these may thus be constructed.

### Embodiment 1

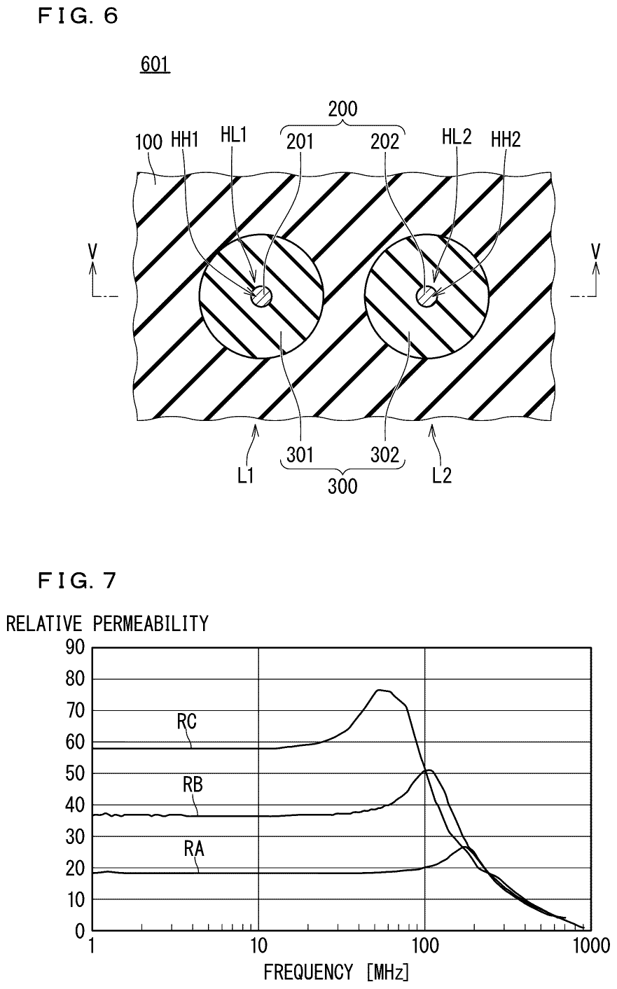

FIG. 5 is a diagram schematically illustrating a structure of the core substrate 601 in Embodiment 1, and is a partial cross-sectional view taken along the line V-V of FIG. 6. FIG. 6 is a partial cross-sectional view taken along the line VI-VI of FIG. 5. The core substrate 601 includes the inductors L1 and L2, and an insulator substrate 100 including through holes HL1 and HL2 in which the inductors L1 and L2 are disposed, respectively. The inductors L1 and L2 include at least one conductor portion, and may include a plurality of conductor portions including conductor portions 201 and 202. Each of the conductor portions may be hereinafter generically referred to as a conductor portion 200. The inductors L1 and L2 include at least one magnetic substance portion, and may include a plurality of magnetic substance portions including magnetic substance portions 301 and 302. Each of the magnetic substance portions may be hereinafter generically referred to as a magnetic substance portion 300. Each of the magnetic substance portions 300 includes a plurality of magnetic substance segments (specifically, magnetic substance segments MA to MC), which will be described later in detail. The core substrate 601 may include an interconnector 450 (a terminal), an electrode portion 401 (a terminal), and an electrode portion 402 (a terminal).

The insulator substrate 100 has the first surface SF1, and the second surface SF2 opposite the first surface SF1 in a thickness direction. The insulator substrate 100 is a ceramic substrate or a resin substrate. Embodiment 1 will mainly describe, in detail, a case where the insulator substrate 100 is a ceramic substrate. The ceramic substrate is made of a ceramic sintered body. The ceramic sintered body does not substantially contain an organic component, and may contain a glass component. In other words, the ceramic substrate may be made of a glass ceramic. The ceramic substrate is desirably made of LTCC. The LTCC is ceramics that can be sintered approximately at 900° C. or lower by adding an additive such as a glass component to ceramics. Since the LTCC can be sintered at a temperature sufficiently lower than the melting point of Ag, AgPd, or Cu, the LTCC with a built-in conductor containing Ag, AgPd, or Cu as a main component and having a low electrical resistance can be co-sintered with the conductor. The insulator substrate 100 includes the through holes HL1 and HL2 between the first surface SF1 and the second surface SF2. The insulator substrate 100 preferably has a coefficient of thermal expansion of 4 ppm/° C. or higher and 16 ppm/° C. or lower. The insulator substrate 100 preferably has a relative permittivity of 8 or less and a dielectric dissipation factor of 0.01 or less at 1 GHz.

The conductor portion 201 extends through a through hole HH1 in the magnetic substance portion 301. Similarly, the conductor portion 202 extends through a through hole HH2 in the magnetic substance portion 302. Since the through holes HL1 and HL2 include the through hole HH1 and HH2, respectively, it can be said that the conductor portions 201 and 202 extend through the through holes HL1 and HL2, respectively. Each of these conductor portions 200 (i.e., the conductor portions 201 and 202) may be a non-hollow body. In other words, each of the conductor portions 200 need not have a hollow interior. Furthermore, the conductor portions 200 are made of a sintered material containing sintered metal. This sintered metal includes at least one of Ag, AgPd, or Cu, for example. The sintered material for the conductor portions 200 may contain a ceramic material, which has a conductivity lower than the sintered metal, to the extent that the function of the conductor portions 200 as electrical wiring is maintained. A proportion of the ceramic material to the sintered metal is preferably 5 vol % or more and 30 vol % or less. Adding the ceramic material to the material of the conductor portions 200 enhances bonding between the conductor portions 200 and the magnetic substance portions 300. The ceramic material preferably has a particle size of 0.5 μm or more and 10 μm or less. Examples of the ceramic material include alumina, zirconia, magnesium oxide, and titanium oxide.

The conductor portion 201 may approximately linearly extend along the thickness direction. Specifically, the conductor portion 201 may extend along the thickness direction so as not to deviate from a straight line along the thickness direction as a virtual axis. In other words, the conductor portion 201 may have a virtual axis extending through the conductor portion 201 in the whole range where the conductor portion 201 is disposed in the thickness direction; the virtual axis is a straight line along the thickness direction. The conductor portion 202 may have the characteristics on extension of this conductor portion 201.

The magnetic substance portion 301 surrounds the conductor portion 201 in the through hole HL1, and the magnetic substance portion 302 surrounds the conductor portion 202 in the through hole HL2. The magnetic substance portion 301 and the magnetic substance portion 302 may be in direct contact with the conductor portion 201 and the conductor portion 202, respectively. Each of the magnetic substance portions 300 may have a circular inner edge and a circular outer edge in cross section (FIG. 6) perpendicular to the thickness direction. The inner edge and the outer edge may have another shape in place of the circular shape, and may have an elliptical shape, or a polygonal shape such as a quadrilateral shape, for example. Corners of the polygonal shape may be chamfered. Each of the magnetic substance portions 300 may extend approximately in the thickness direction, and may be approximately cylindrical when, particularly, the inner edge and the outer edge are approximately circular. Each of the conductor portions 200 may have a circular edge in cross section (FIG. 6) perpendicular to the thickness direction. This edge may have another shape in place of the circular shape, and may have an elliptical shape, or a polygonal shape such as a quadrilateral shape, for example. Corners of the polygonal shape may be chamfered. Each of the conductor portions 200 may extend approximately in the thickness direction, and may be approximately columnar when, particularly, the edge is approximately circular.

The magnetic substance portions 300 are made of ceramics (a ceramic sintered body), and do not contain an organic component. To reduce the volume of the inductors, a magnetic material for the magnetic substance portions 300 desirably has a high permeability, and the magnetic substance portions 300 preferably have a denseness of 70% or more. To reduce an electrical loss of the inductors, the magnetic material for the magnetic substance portions 300 is desirably a soft magnetic material having a small magnetic loss at a high frequency, and is desirably a soft magnetic material having a magnetic loss tangent of 0.1 or less at a frequency of 100 MHz, for example. To reduce a magnetic loss at a high frequency, the magnetic material for the magnetic substance portions 300 desirably has a high volume electrical resistivity, and specifically desirably has a volume electrical resistivity of 1 MΩ cm or higher. The magnetic substance portions 300 are preferably made of a ferrite-based material. A crystalline structure of this material is preferably a spinel structure in terms of ease of manufacture. For example, Ni-Zn-based ferrite or Ni-Zn-Cu-based ferrite is used as the crystalline structure. The crystalline structure is preferably a hexagonal structure having a c-axis orientation along the thickness direction (a vertical direction in FIG. 5) in terms of a high permeability.

A method of manufacturing an inductor includes a firing step, which will be described later in detail. In this firing step, the conductor portions 200 (the conductor portions 201 and 202) and the magnetic substance portions 300 (the magnetic substance portions 301 and 302) are fired. Thus, an inorganic material for the conductor portions 200 and an inorganic material for the magnetic substance portions 300 are bonded together without an organic material between them. In other words, the conductor portions 200 and the magnetic substance portions 300 are inorganically bonded together. Specifically, the conductor portions 200 and the magnetic substance portions 300 are sintered together. The insulator substrate 100 in the core substrate 601 may be co-fired. In such a case, the inorganic material for the magnetic substance portions 300 and an inorganic material for the insulator substrate 100 are thus bonded together without an organic material between them. In other words, the magnetic substance portions 300 and the insulator substrate 100 are inorganically bonded together. Specifically, the magnetic substance portions 300 and the insulator substrate 100 are sintered together.

The interconnector 450 electrically connects one end of the conductor portion 201 and one end of the conductor portion 202 on the first surface SF1 of the insulator substrate 100. On the second surface SF2 of the insulator substrate 100, the electrode portion 401 is connected to the other end of the conductor portion 201, and the electrode portion 402 is connected to the other end of the conductor portion 202. The electrode portion 401 and the electrode portion 402 are separated from each other. Thus, the one end of the conductor portion 201 and the one end of the conductor portion 202 are electrically connected to each other, and the other end of the conductor portion 201 and the other end of the conductor portion 202 are electrically separated from each other. A circuit illustrated in FIG. 4 is thereby constructed.

The electrode portion 401 faces each of the conductor portion 201 and the magnetic substance portion 301 in the thickness direction (a vertical direction in FIG. 5). The electrode portion 402 faces each of the conductor portion 202 and the magnetic substance portion 302 in the thickness direction (vertical direction in FIG. 5). The interconnector 450 faces each of the conductor portions 201 and 202, and the magnetic substance portions 301 and 302 in the thickness direction (vertical direction in FIG. 5).

At least one of (preferably each of) the electrode portions 401, 402 and the interconnector 450 is preferably a terminal made of a sintered material containing sintered metal, and the sintered material may contain a small amount of glass component in addition to the sintered metal. The sintered metal contains Ag, AgPd, or Cu as a main component, for example. The electrode portion 401 and each of the conductor portion 201 and the magnetic substance portion 301 are preferably inorganically bonded together. Furthermore, the electrode portion 402 and each of the conductor portion 202 and the magnetic substance portion 302 are preferably inorganically bonded together. Furthermore, the interconnector 450 and each of the conductor portions 201, 202 and the magnetic substance portions 301, 302 are preferably inorganically bonded together.

A design example of the core substrate 601 (FIGS. 5 and 6) will be described below. The insulator substrate 100 has a square shape with sides of 50 mm in an in-plane direction, and has a dimension of 550 μm in the thickness direction. The plurality of through holes (e.g., the through holes HL1 and HL2) are arranged at a pitch of 450 μm. The insulator substrate 100 is made of an LTCC material containing Ba-Si-Al-O elements as a main component, or glass alumina, for example. Each of the magnetic substance portions 300 has an outer diameter of 350 μm and an inner diameter of 100 μm. Each of the conductor portions 200 has an outer diameter of 100 μm. The conductor portions 200 are formed by sintering Ag or AgPd powder. The magnetic substance portions 300 are made of a ferrite-sintered body, and its effective relative permeability is estimated to be 16. In this case, a single inductor (e.g., the inductor L1) has an inductance of approximately 2 nH at 140 MHz according to estimates of the inventors. Thus, a serial connection of two inductors results in an inductance of approximately 4 nH.

Next, a structure of each of the inductors of the core substrate 601 will be described. Although the structure of the inductor L1 will be hereinafter described in detail, the other inductors (e.g., the inductor L2) may have the same structure.

The inductor L1 is disposed in the through hole HL1 of the insulator substrate 100, and includes the conductor portion 201 and the magnetic substance portion 301. The magnetic substance portion 301 includes a plurality of magnetic substance segments disposed at different positions in one direction. The one direction is, for example, a direction in which each of the conductor portions 201 and 202 extends (the vertical direction in FIG. 5). Each of the magnetic substance segments is penetrated by the conductor portion 201 and inorganically bonded to the conductor portion 201. The plurality of magnetic substance segments include at least one magnetic substance segment MA (a first magnetic substance segment), and at least one magnetic substance segment MB (a second magnetic substance segment). In Embodiment 1, each of the at least one magnetic substance segment MA and the at least one magnetic substance segment MB is one magnetic substance segment. The plurality of magnetic substance segments may further include another magnetic substance segment, and include a magnetic substance segment MC in Embodiment 1. The magnetic substance segments MA, MB, and MC are made of a first magnetic material, a second magnetic material, and a third magnetic material, respectively.

FIG. 7 is a graph exemplifying the frequency dependences of the relative permeabilities RA to RC of the first to third magnetic materials. The relative permeabilities of the first to third magnetic materials peak at the first to third frequencies, respectively, and the first to third frequencies are different from each other. In a frequency region sufficiently lower than the peak, the relative permeability does not have a strong frequency dependence, and has an almost flat frequency characteristic. Thus, the higher the peak frequency is, the wider frequency region with almost a flat frequency characteristic can be ensured. On the other hand, the higher the value of the relative permeability is, the more the inductance of the inductor L1 can be increased. Thus, the magnetic material for the magnetic substance portion 301 preferably has both a high peak frequency and a high relative permeability, which often have a trade-off relationship. Specifically, in the relative permeabilities RA to RC of the first to third magnetic materials, although the relative permeability RA is relatively inferior in terms of the value of the relative permeability in the almost flat frequency characteristic region, the relative permeability RA is relatively superior in terms of the peak frequency. Conversely, although the relative permeability RC is relatively inferior in terms of the peak frequency, the relative permeability RC is relatively superior in terms of the value of the relative permeability in the almost flat frequency characteristic region. The relative permeability RB has intermediate characteristics between the relative permeability RA and the relative permeability RC. When the inductor L1 is for an interposer, the peak frequency may be considered in, for example, a frequency range of 1 MHz or higher.

If the whole magnetic substance portion 301 is made of the third magnetic material with the relative permeability RC, the almost flat frequency characteristic region can hardly be ensured widely although the sufficient inductance magnitude is easily ensured because the value of the relative permeability RC is high. If the whole magnetic substance portion 301 is made of the first magnetic material with the relative permeability RA, although the almost flat frequency characteristic region is ensured widely, the sufficient inductance magnitude can hardly be ensured because the value of the relative permeability RA is low. If the whole magnetic substance portion 301 is made of the second magnetic material with the relative permeability RB, the intermediate characteristics in the aforementioned trade-off relationship are merely obtained. As such, simply selecting the magnetic material for the magnetic substance portion 301 can hardly suppress the frequency dependence of the inductance while maintaining the sufficient inductance of the inductor L1. In contrast, the magnetic substance portions 300 according to Embodiment 1 are built by combining the first to third magnetic materials with the relative permeabilities RA to RC, respectively.

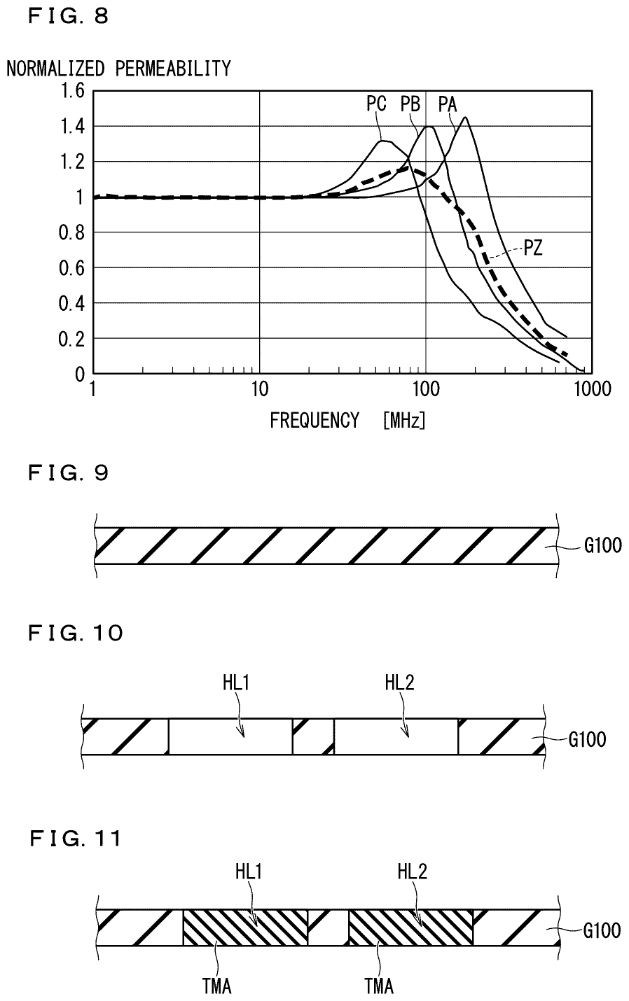

FIG. 8 is a graph exemplifying the frequency dependences of permeabilities PA to PC of the first to third magnetic materials and an effective permeability PZ of a magnetic substance portion using the combination of the first to third magnetic materials. The values of the vertical axis of this graph are normalized by values at a frequency (1 MHz herein) sufficiently lower than the peak frequencies.

Assuming that, for example, ±20% variations in the permeabilities are tolerated in view of the frequency characteristics of the inductor L1, when the third magnetic material with the permeability PC is used, use only up to approximately 40 MHz is allowed. When the second magnetic material with the permeability PB is used, use only up to approximately 80 MHz is allowed. When the first magnetic material with the permeability PA is used, although use nearly up to 200 MHz is allowed, the first magnetic material has a drawback of the considerably low relative permeability RA (FIG. 7). In contrast, the effective permeability PZ of the magnetic substance portion 301 according to Embodiment 1, which has been built by combining the first to third magnetic materials, has a large peak width and a suppressed peak value, because the first to third magnetic materials have different peak frequencies. Consequently, assuming that ±20% variations in the permeability are tolerated as described above, use approximately up to 200 MHz is allowed. Furthermore, the magnetic substance portion 301 according to Embodiment 1 facilitates ensuring the sufficient inductance by using the magnetic materials with the relative permeabilities RB and RC (FIG. 7) higher than the relative permeability RA (FIG. 7).

A thickness ratio between the magnetic substance segments MA, MB, and MC may be adjusted according to the magnetic properties of the first to third magnetic materials to obtain a desired effective permeability PZ. In the example of FIG. 7, for example, the relative permeabilities of the first magnetic material, the second magnetic material, and the third magnetic material in the almost flat frequency characteristic region are approximately 20, 36, and 58, respectively. Assuming that, in view of the permeabilities, a preferred thickness ratio between the magnetic substance segments MA, MB, and MC is estimated to be 100:56:34. Here, when the thickness of each of the magnetic substance segments is designed in increments of 50 μm due to manufacturing reasons, the thicknesses of the magnetic substance segments MA, MB, and MC are set to, for example, 300 μm, 150 μm, and 100 μm, respectively.

As described above, Embodiment 1 suppresses the influence of each of the peaks on the frequency dependence of the inductance without significantly sacrificing the permeability. Thus, Embodiment 1 can suppress the frequency dependence of the inductance while maintaining the sufficient inductance.

Moreover, Embodiment 1 employs the one magnetic substance segment MA and the one magnetic substance segment MB, whereas Embodiment 3 (FIG. 22) to be described later employs a plurality of magnetic substance segments MA and a plurality of magnetic substance segments MB. This can reduce the number of interfaces between the magnetic substance segments made of different magnetic materials. This can suppress interdiffusion of elements between different materials. This can suppress worsening of the magnetic properties due to the interdiffusion.

The magnetic substance portions 300 (FIG. 5) are not made of a resin in which magnetic particles are dispersed, but are made of a ceramic sintered body. This can facilitate increasing the permeability of the magnetic substance portions 300 by densely sintering the ceramic. In particular, when the magnetic substance portions 300 have a denseness of 70% or more, the permeability of the magnetic substance portions 300 is easily sufficiently increased.

The conductor portions 200 are made of a sintered material containing sintered metal. Variations in electrical characteristics, in particular, variations of conductivity of the conductor portions 200 can thus be suppressed more than that when the conductor portions 200 are plating films. Electrical characteristics of the core substrate can thus be stabilized.

The conductor portions 200 may be non-hollow bodies. Electrical resistance of the conductor portions 200 can thereby be reduced.

The conductor portions 200 and the magnetic substance portions 300 are bonded together without an organic material between them. In other words, the conductor portions 200 and the magnetic substance portions 300 are inorganically bonded together. Specifically, the conductor portions 200 and the magnetic substance portions 300 are sintered together. Heat resistance of the core substrate 601 can thereby be increased more than that when the conductor portions 200 and the magnetic substance portions 300 are bonded together through an organic material.

When the magnetic substance portions 300 each have the circular inner edge and the circular outer edge in a cross-sectional view (FIG. 6) perpendicular to the thickness direction, the magnetic substance portions 300 can be disposed isotropically with respect to the conductor portions 200 in the cross section.

In the case where the magnetic substance portions 300 are made of an insulator, even when the magnetic substance portions 300 are in direct contact with the conductor portions 200 as illustrated in FIG. 5, diffusion of a current from the conductor portions 200 to the magnetic substance portions 300 can be avoided. Direct contact of the magnetic substance portions 300 with the conductor portions 200 facilitates sufficiently reserving a region in which the magnetic substance portions 300 are disposed.

The core substrate 601 includes the inductor L1 including the conductor portion 201 and the magnetic substance portion 301, and the inductor L2 including the conductor portion 202 and the magnetic substance portion 302. The plurality of inductors can thereby be built in the core substrate 601.

The interconnector 450 electrically connects one end (the lower end in FIG. 5) of the conductor portion 201 and one end (the lower end in FIG. 5) of the conductor portion 202 on the first surface SF1 of the insulator substrate 100. Thereby, the inductor L1 including the conductor portion 201 and the magnetic substance portion 301 can be electrically connected to the inductor L2 including the conductor portion 202 and the magnetic substance portion 302.

When the other end (an upper end in FIG. 5) of the conductor portion 201 and the other end (an upper end in FIG. 5) of the conductor portion 202 are electrically separated from each other as illustrated in FIG. 5, the inductor L1 including the conductor portion 201 and the magnetic substance portion 301 and the inductor L2 including the conductor portion 202 and the magnetic substance portion 302 are connected not in parallel but in series. This can increase the combined inductance.

Furthermore, when the insulator substrate 100 is a ceramic substrate, the ceramic substrate and the magnetic substance portions 300 may be inorganically bonded together. Thus, a resin for bonding the insulator substrate 100 and the magnetic substance portions 300 together need not be used. This can avoid reduction in heat resistance of the core substrate 601 due to the use of the resin.

When the insulator substrate 100 is a ceramic substrate, the insulator substrate 100 has stiffness higher than that of a resin substrate. The insulator substrate 100 resists warping even after addition of another component to the insulator substrate 100. The core substrate 601 having smaller warpage can thus be obtained. Suppressing warpage will improve, first, the formation yield of the wiring layer 791 and the wiring layer 792 (FIG. 1), in particular, the yield of the wiring layer 791 including the wiring structure having a high density. Second, the mounting yield of the semiconductor element 811 (FIG. 1) will be improved.

When the insulator substrate 100 is a ceramic substrate, the ceramic substrate facilitates setting its thermal expansion coefficient in a range of 4 ppm/° C. or higher and 16 ppm/° C. or lower. This can set the thermal expansion coefficient of the insulator substrate 100 between the thermal expansion coefficient of the semiconductor element 811 (FIG. 1) to be mounted on the interposer 700 including the core substrate 601 and the thermal expansion coefficient of the typical motherboard 812 (FIG. 1) on which the interposer 700 is to be mounted. Warpage in the electronic equipment 901 (FIG. 1) or the electronic equipment 902 (FIG. 2) due to thermal expansion and contraction can thereby be suppressed.

Next, an example method of manufacturing the core substrate 601 (FIG. 5) including the inductors L1 and L2 will be described with reference to FIGS. 9 to 17.

A green sheet G100 (FIG. 9) to be the insulator substrate 100 (FIG. 5) through firing is prepared. The thickness of the green sheet G100 is, for example, 0.1 mm or less. The through holes HL1 and HL2 (FIG. 10) are formed by, for example, punching the green sheet G100. The planar shape of each of the through holes HL1 and HL2 is, for example, a circular shape of approximately 0.4 mm in diameter.

The through holes HL1 and HL2 are filled with magnetic substance paste portions TMA (FIG. 11) to be the magnetic substance segments MA (FIG. 5) through firing. This filling is performed by, for example, printing a magnetic substance paste.

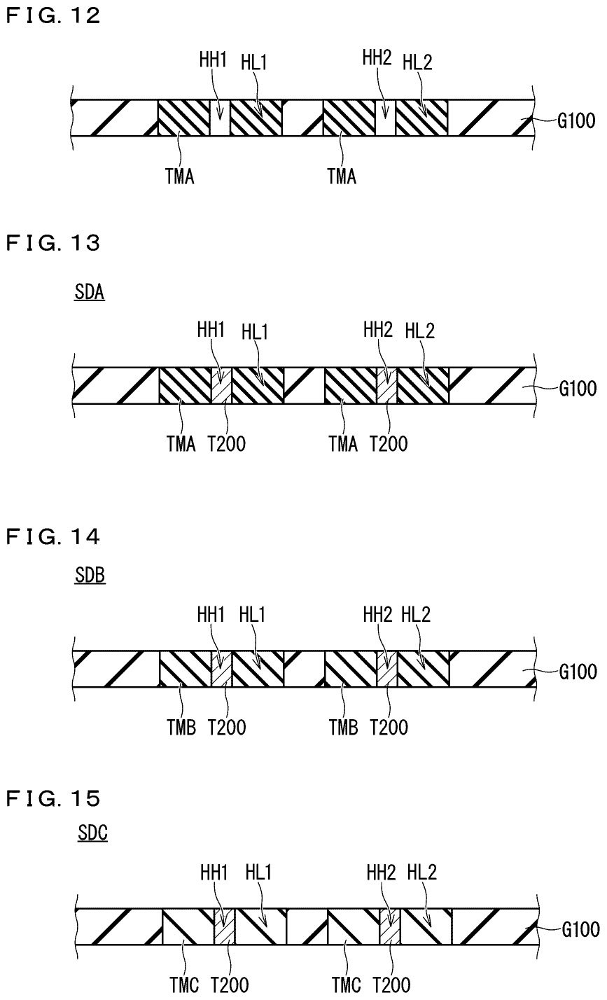

The through holes HH1 and HH2 (FIG. 12) are formed by, for example, laser processing the magnetic substance paste portion TMA in the through hole HL1 and the magnetic substance paste portion TMA in the through hole HL2, respectively. The planar shape of each of the through holes HH1 and HH2 is, for example, a circular shape of approximately 0.1 mm in diameter.

The through holes HH1 and HH2 are filled with conductor paste portions T200 (FIG. 13) to be the conductor portions 200 through firing, which results in a sheet SDA (FIG. 13). This filling is performed by, for example, printing a conductor paste. The conductor paste contains, for example, Ag powder, AgPd powder, or Cu powder, and an organic binder.

A sheet SDB (FIG. 14) containing, in place of the magnetic substance paste portions TMA, magnetic substance paste portions TMB to be the magnetic substance segments MB (FIG. 5) through firing is formed according to the same method described above. Furthermore, a sheet SDC (FIG. 15) containing, in place of the magnetic substance paste portions TMA, magnetic substance paste portions TMC to be the magnetic substance segments MC (FIG. 5) through firing is formed.

Stacking at least one sheet SDA, at least one sheet SDB, and at least one sheet SDC form a stack GP (FIG. 16). This stacking may involve heating and pressing, and involves, for example, heating at 100° C. and pressing at 4 MPa. In the illustrated example, four sheets SDA, three sheets SDB, and one sheet SDC are stacked. Adjusting the number of sheets can adjust the thickness of each of the magnetic substance segments MA to MC.

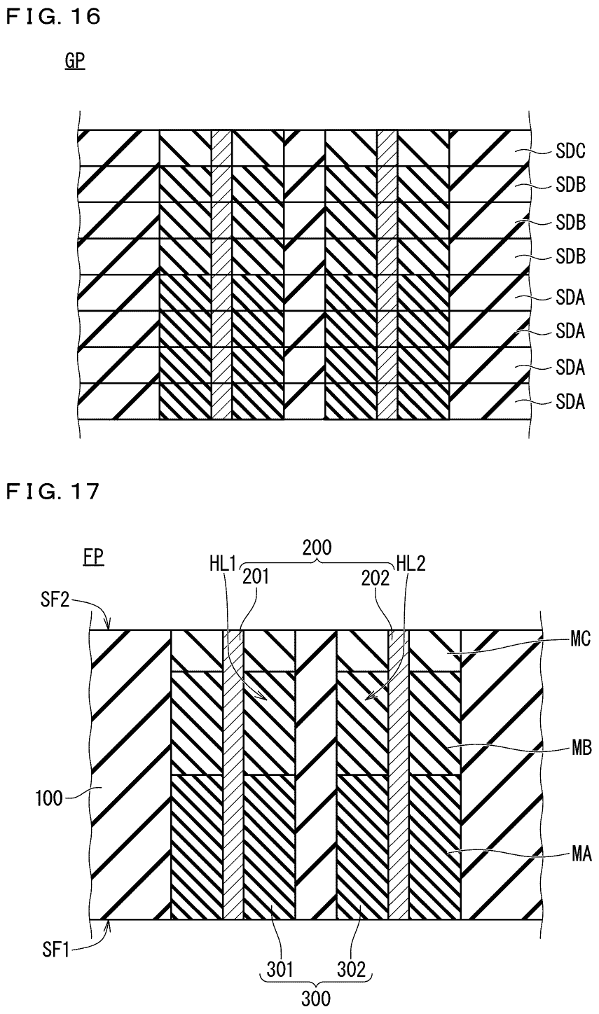

Firing the stack GP forms a fired body FP (FIG. 17). The stack GP is fired, for example, at 900° C. for two hours. Then, electrode paste portions (not illustrated) to be the electrode portions 401 and 402 and the interconnector 450 are formed. The electrode paste portions are formed by, for example, printing an electrode paste. The electrode paste includes, for example, Ag powder, an organic binder, and a small amount of glass. Next, these electrode paste portions are fired. The electrode paste portions are fired, for example, at 850° C. for ten minutes. These obtain the core substrate 601 (FIG. 5).

### Embodiment 2

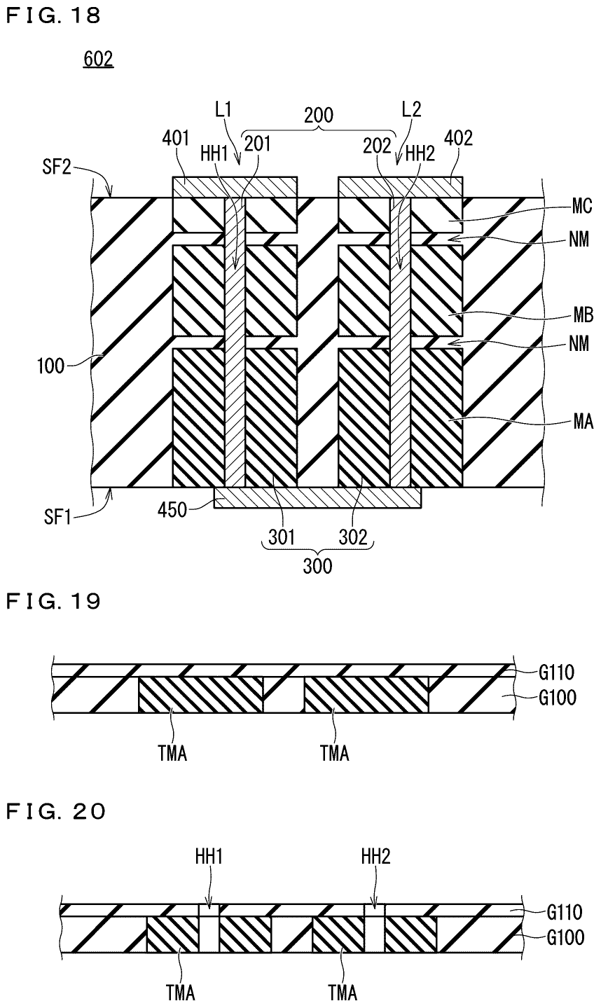

FIG. 18 is a partial cross-sectional view schematically illustrating a structure of a core substrate 602 in Embodiment 2. In the core substrate 602, at least one magnetic substance segment MA and at least one second magnetic substance segment MB are separated in the thickness direction (one direction) by separation portions NM made of a non-magnetic material. As illustrated in FIG. 18, the separation portions NM may be built by penetration of the insulator substrate 100. In such a case, the separation portions NM are made of the same material as that of the insulator substrate 100. The structure except the separation portions NM is substantially the same as the aforementioned structure in Embodiment 1, so that the same or corresponding components bear the same reference signs, and description thereof is not repeated.

Next, an example method of manufacturing the core substrate 602 (FIG. 18) will be hereinafter described.

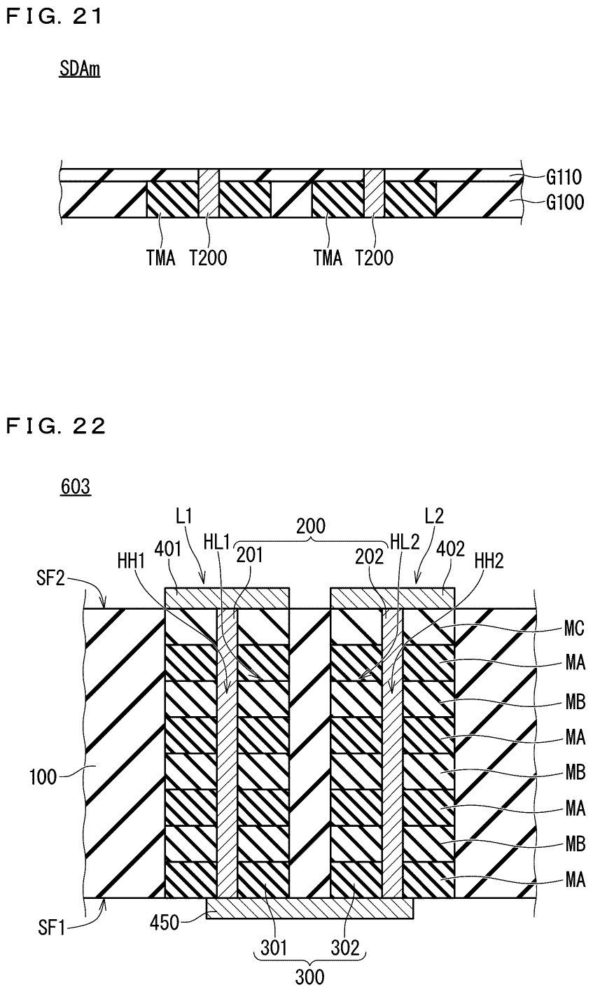

A film G110 (FIG. 19) including a portion to be the separation portion NM through firing is formed on the sheet obtained through the steps illustrated in FIGS. 9 to 11 by, for example, applying paste. The film G110 may be made of the same material as that of a green sheet G100. Next, the through holes HH1 and HH2 (FIG. 20) are formed to extend through the film G110 and the magnetic substance paste portions TMA. Next, the through holes HH1 and HH2 are filled with the conductor paste portions T200 (FIG. 21) to be the conductor portions 200 through firing, which results in a sheet SDAm (FIG. 21). This sheet SDAm is obtained by adding the film G110 for forming the separation portion NM (FIG. 18) to the sheet SDA (FIG. 13). A sheet obtained by adding the film G110 to the sheet SDB and a sheet obtained by adding the film G110 to the sheet SDC may be formed in the same method as necessary. As such, at least one sheet to which the film G110 is added is used in forming the stack GP (FIG. 16: Embodiment 1). Then, the core substrate 602 is obtained through the same steps as those of Embodiment 1.

According to Embodiment 2, the at least one magnetic substance segment MA and the at least one magnetic substance segment MB are separated in the thickness direction by the separation portion NM made of a non-magnetic material. This separation portion NM can suppress the interdiffusion of elements in the firing step between the magnetic substance segment MA and the magnetic substance segment MB. This can suppress worsening of the magnetic properties due to the interdiffusion. The thickness of the separation portion NM may be determined to produce sufficient advantages, and is, for example, 10 μm or more.

The feature of the separation portion NM in Embodiment 2 may be applied to Embodiments 3 to 6 (including its modifications) to be described later.

### Embodiment 3

FIG. 22 schematically illustrates a structure of a core substrate 603 in Embodiment 3. The aforementioned inductor L1 (FIG. 5: Embodiment 1) includes one magnetic substance segment MA as at least one magnetic substance segment MA. In contrast, the inductor L1 according to Embodiment 3 includes a plurality of magnetic substance segments MA as the at least one magnetic substance segment MA. The plurality of magnetic substance segments MA include two magnetic substance segments MA separated by the magnetic substance segment MB.

Furthermore, the aforementioned inductor L1 (FIG. 5: Embodiment 1) includes one magnetic substance segment MB as at least one magnetic substance segment MB. In contrast, the inductor L1 according to Embodiment 3 includes a plurality of magnetic substance segments MB as the at least one magnetic substance segment MB. The plurality of magnetic substance segments MB include two magnetic substance segments MB separated by the magnetic substance segment MA.

The other structure is substantially the same as the aforementioned structure in Embodiment 1, so that the same or corresponding components bear the same reference signs, and description thereof is not repeated. Since the core substrate 603 is obtained by changing the order of stacking the sheets SDA to SDC (FIG. 16) in the method of manufacturing the core substrate 601, detailed description of the manufacturing method is omitted.

According to Embodiment 3, the magnetic substance segments MB made of the second magnetic material are disposed not in only one portion but dispersively in a plurality of portions, unlike the core substrate 601 (FIG. 5: Embodiment 1). Thus, the magnetic property distribution in the thickness direction (a vertical direction in FIG. 22) of the magnetic substance portion 301 can be made more uniform.

The features described in Embodiment 3 (e.g., the feature in that the magnetic substance segments MB made of the second magnetic material are disposed not in only one portion but dispersively in a plurality of portions) may be applied to Embodiments 4 to 6 (including its modifications) to be described later.

### Embodiment 4

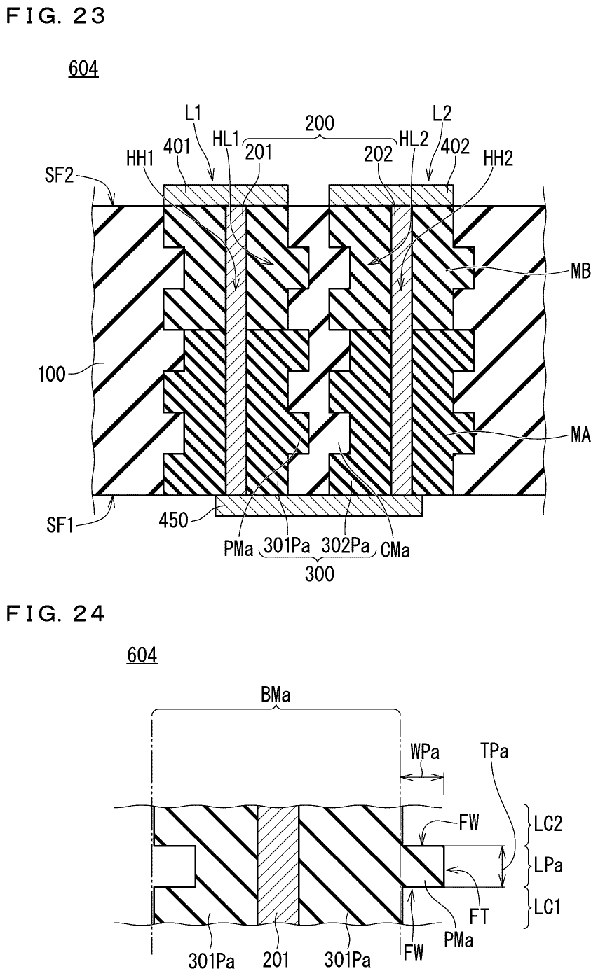

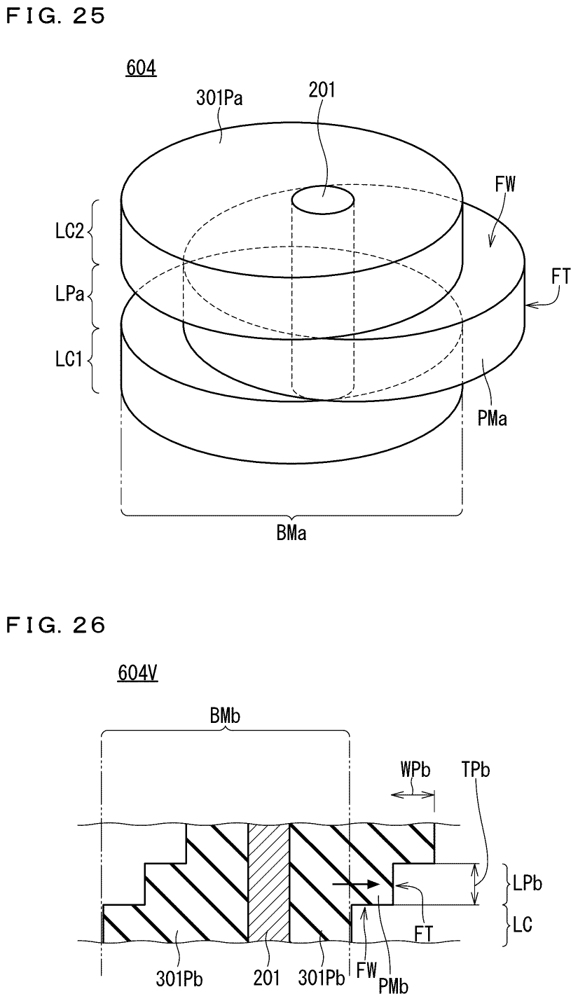

FIG. 23 is a partial cross-sectional view schematically illustrating a structure of a core substrate 604 in Embodiment 4. FIG. 24 is a partial enlarged view of FIG. 23. FIG. 25 is a perspective view of FIG. 24.

The core substrate 604 (FIG. 23) includes magnetic substance portions 301Pa and 302Pa in place of the magnetic substance portions 301 and 302 of the core substrate 601 (FIG. 5). Each of the magnetic substance portions 301Pa and 302Pa includes a plurality of magnetic substance segments, similarly to the magnetic substance portions 301 and 302. FIG. 23 exemplifies that each of the magnetic substance portions 301Pa and 302Pa includes the magnetic substance segments MA and MB. Each of the magnetic substance portions 301Pa and 302Pa includes a protruding structure PMa toward the insulator substrate 100, in a cross section view including the thickness direction (a vertical direction in FIG. 23). Specifically, each of the magnetic substance portions 301Pa and 302Pa includes the protruding structure PMa into the insulator substrate 100, in the cross section view including the thickness direction (vertical direction in FIG. 23).

The core substrate 604 includes a layer LC1, a layer LC2, and a layer LPa between the layer LC1 and the layer LC2 in the thickness direction (a vertical direction in FIG. 24). The layer LPa is in contact with each of the layer LC1 and the layer LC2. In other words, the layer LC1, the layer LPa, and the layer LC2 are directly stacked in order in the thickness direction. The layer LC1, the layer LPa, and the layer LC2 may correspond to layers stacked when the core substrate 604 is manufactured using the laminated ceramic technology.

The magnetic substance portion 301Pa (FIG. 24) falls within a range BMa in an in-plane direction (a direction perpendicular to the thickness direction) in each of the layer LC1 and the layer LC2, and protrudes beyond the range BMa in the layer LPa. A portion of the magnetic substance portion 301Pa protruding beyond the range BMa corresponds to a protruding structure PMa. Although arrangements of the magnetic substance portion 301Pa in the layer LC1 and the layer LC2 in the in-plane direction are the same in an example illustrated in FIG. 24, these arrangements may be the same or different from each other as long as the magnetic substance portion 301Pa fall within the range BMa. A minimum range within which the magnetic substance portion 301Pa falls in both of the layer LC1 and the layer LC2 is the range BMa.

The protruding structure PMa has a thickness dimension TPa and a width dimension WPa (a dimension in the direction perpendicular to the thickness direction). The protruding structure PMa may be substantially rectangular in a cross-sectional view as illustrated in FIG. 24. In this case, the width dimension WPa and the thickness dimension TPa correspond to dimensions of sides of the rectangle. When the protruding structure PMa is formed using the laminated ceramic technology as described above, the rectangular protruding structure PMa can easily be formed. In this case, the protruding structure PMa has a pair of surfaces FW substantially parallel to the in-plane direction and an end surface FT substantially parallel to the thickness direction. For example, as illustrated in FIG. 25 (the perspective view), a pattern (a shape in the in-plane direction) of the magnetic substance portion 301Pa in each of the layer LC1, the layer LPa, and the layer LC2 may have a circular outer edge. Furthermore, the protruding structure PMa may be formed by displacing the pattern in the layer LPa from the pattern in each of the layer LC1 and the layer LC2. As a modification, the protruding structure can be formed by increasing a diameter of a circular shape in the layer LPa more than a diameter of a circular shape in each of the layer LC1 and the layer LC2, instead of displacing the pattern as described above.

The protruding structure PMa (FIG. 24) may be rectangular in a cross-sectional view as described above, or may have another shape. A maximum width dimension and a maximum thickness dimension of the protruding structure PMa may be considered as the width dimension WPa and the thickness dimension TPa, respectively. The width dimension WPa and the thickness dimension TPa are each greater than the particle size of the ceramic contained in the insulator substrate 100. When the particle size is 1 μm or more and 10 μm or less, the width dimension WPa is preferably 10 μm or more and 100 μm or less. When the width dimension WPa is 10 μm or more, the protruding structure PMa facilitates sufficiently producing an anchoring effect. When the width dimension

WPa is 100 μm or less, cracks of the insulator substrate 100 due to thermal stress concentration near the protruding structure PMa are easily avoided. The thickness dimension TPa is preferably 50 μm or more and 200 μm or less.

The magnetic substance portion 302Pa may have the aforementioned protruding structure PMa. As illustrated in the cross-sectional view in FIG. 23, the protruding structure PMa of the magnetic substance portion 301Pa and a recessed structure CMa of the magnetic substance portion 302Pa may face each other in the in-plane direction (a horizontal direction in FIG. 23).

The other structure of the core substrate 604 is substantially the same as the aforementioned structure of the core substrate 601 (FIG. 5: Embodiment 1), so that the same or corresponding components bear the same reference signs, and description thereof is not repeated.

According to Embodiment 4, mechanical bonding between each of the magnetic substance portions 301Pa and 302Pa and the insulator substrate 100 is enhanced by the protruding structure PMa. Deterioration of electrical characteristics of the core substrate 604 with temperature cycling is thereby suppressed. The electrical characteristics of the core substrate 604 can thus further be stabilized.

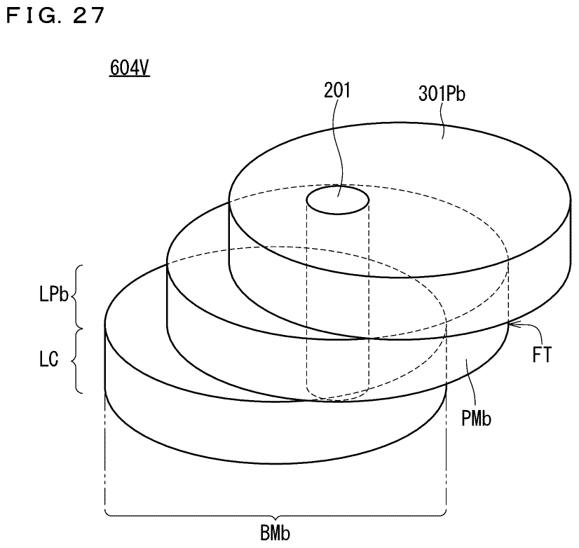

FIG. 26 illustrates a core substrate 604V according to a modification of the core substrate 604 (FIG. 24). FIG. 27 is a perspective view of FIG. 26. The core substrate 604V (FIG. 26) includes a magnetic substance portion 301Pb in place of the magnetic substance portion 301Pa of the core substrate 604 (FIG. 24). The magnetic substance portion 301Pb has a step structure PMb facing the insulator substrate 100.

The core substrate 604V includes a layer LC and a layer LPb directly stacked in the thickness direction (a vertical direction in FIGS. 26 and 27). The layer LC and the layer LPb may correspond to layers stacked when the core substrate 604V is manufactured using the laminated ceramic technology.

The magnetic substance portion 301Pb (FIG. 26) falls within a range BMb in an in-plane direction (a direction perpendicular to the thickness direction) in the layer LC, and protrudes beyond the range BMb in the layer LPb. A portion of the magnetic substance portion 301Pb extending beyond the range BMb corresponds to the step structure PMb. The step structure PMb has a surface FW extending from the range BMb substantially parallel to the in-plane direction and an end surface FT extending from an end of the surface FW substantially parallel to the thickness direction. In the cross section (FIG. 26) including the thickness direction, a dimension of the surface FW is defined as a width dimension WPb of the step structure PMb, and a dimension of the end surface FT is defined as a thickness dimension TPb of the step structure PMb. The width dimension WPb and the thickness dimension TPb are each greater than the particle size of the ceramic contained in the insulator substrate 100. When the particle size is 1 μm or more and 10 μm or less, the width dimension WPb is preferably 10 μm or more and 100 μm or less, and the thickness dimension TPb is preferably 50 μm or more and 200 μm or less.

For example, as illustrated in FIG. 27 (the perspective view), a pattern (a shape in the in-plane direction) of the magnetic substance portion 301Pb in each of the layer LC and the layer LPb may have a circular outer edge, and the step structure PMb may be formed by displacing the pattern in the layer LPb from the pattern in the layer LC. As a modification, the step structure can be formed by increasing a diameter of a circular shape in the layer LPb more than a diameter of a circular shape in the layer LC, instead of displacing the pattern.

The layer LC1 and the layer LPa in Embodiment 4 (FIG. 24) described above can respectively be considered as the layer LC and the layer LPb in this modification, so that the core substrate 604 having the protruding structure PMa also has the step structure. The protruding structure PMa facilitates producing the effect of enhancing the mechanical strength more than the step structure PMb without a protruding structure.

The aforementioned feature of the protruding structure PMa or the step structure PMb of the magnetic substance portion may be applied to the other embodiments and its modifications described herein.

### Embodiment 5

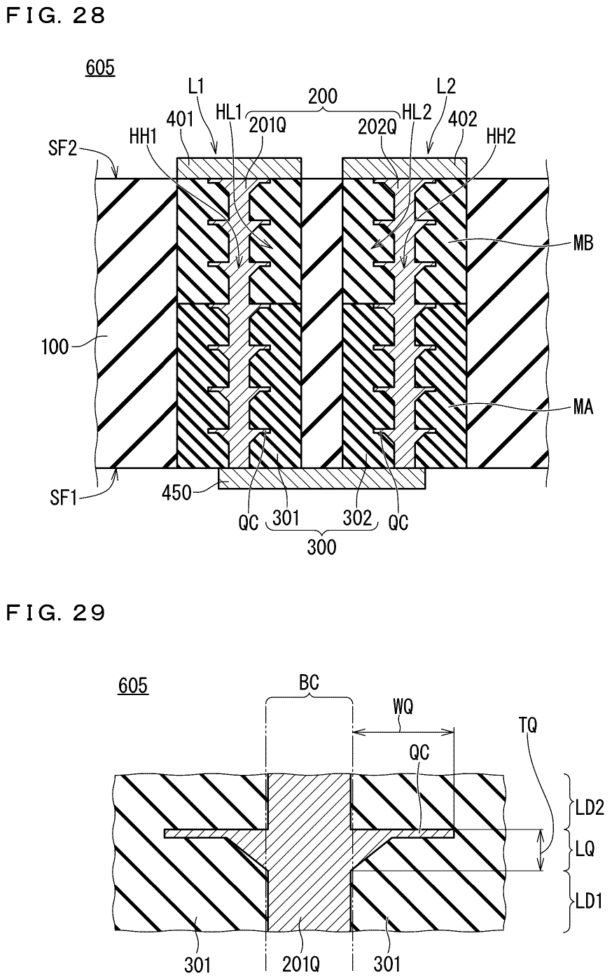

FIG. 28 is a partial cross-sectional view schematically illustrating a structure of a core substrate 605 in Embodiment 5. FIG. 29 is a partial enlarged view of FIG. 28. FIG. 30 is a partial perspective view of FIG. 29.

The core substrate 605 (FIG. 28) includes a conductor portion 201Q and a conductor portion 202Q in place of the conductor portion 201 and the conductor portion 202 of the core substrate 601 (FIG. 5). The conductor portions 201Q and 202Q include protruding structures QC toward the magnetic substance portions 301 and 302, respectively, in a cross section including the thickness direction (a vertical direction in FIG. 29). Specifically, the conductor portions 201Q and 202Q include the protruding structures QC into the magnetic substance portions 301 and 302, respectively, in a cross section view including the thickness direction (vertical direction in FIG. 29). Although each of the magnetic substance portions 301 and 302 includes the magnetic substance segments MA and MB as a plurality of magnetic substance segments in FIG. 28, the structure of the plurality of magnetic substance segments is not limited to this but may further include, for example, the magnetic substance segment MC as illustrated in FIG. 5 (Embodiment 1).

The core substrate 605 includes a layer LD1, a layer LD2, and a layer LQ between the layer LD1 and the layer LD2 in the thickness direction (vertical direction in FIG. 29). The layer LQ is in contact with each of the layer LD1 and the layer LD2. In other words, the layer LD1, the layer LQ, and the layer LD2 are directly stacked in order in the thickness direction. The layer LD1, the layer LQ, and the layer LD2 may correspond to layers stacked when the core substrate 605 is manufactured using the laminated ceramic technology.

The conductor portion 201Q (FIG. 29) falls within a range BC in the in-plane direction (direction perpendicular to the thickness direction) in each of the layer LD1 and the layer LD2, and protrudes beyond the range BC in the layer LQ. A portion of the conductor portion 201Q protruding beyond the range BC corresponds to the protruding structure QC. Although the arrangements of the conductor portion 201Q in the layers LD1 and LD2 in the in-plane direction are the same in an example illustrated in FIG. 29, these arrangements may be the same or different from each other as long as the conductor portion 201Q falls within the range BC. A minimum range within which the conductor portion 201Q falls in both of the layers LD1 and LD2 is the range BC.

The protruding structure QC has a thickness dimension TQ and a width dimension WQ (a dimension in the direction perpendicular to the thickness direction). A maximum width dimension and a maximum thickness dimension of the protruding structure QC may be considered as the width dimension WQ and the thickness dimension TQ, respectively.

The width dimension WQ and the thickness dimension TQ are each greater than a particle size of the sintered metal contained in the magnetic substance portions 300. When the particle size is 0.1 μm or more and 3 μm or less, the width dimension WQ is preferably 10 μm or more and 100 μm or less. The thickness dimension TQ is preferably 5 μm or more and 30 μm or less. When these dimensions are not extremely small, the protruding structure QC facilitates sufficiently producing the anchoring effect. When these dimensions are not extremely large, cracks of the magnetic substance portions 300 due to thermal stress concentration near the protruding structure QC are easily avoided.

As illustrated in FIG. 30 (the perspective view), the protruding structure QC may include a disc portion QCa substantially being disc-shaped, and a frustoconical portion QCb substantially being frustoconical. The protruding structure QC may be sandwiched between cylindrical portions CL substantially being cylindrical in the thickness direction. The disc portion QCa is in contact with a bottom surface of the frustoconical portion QCb (a larger one of two circular surfaces of the frustoconical portion). A central axis of the disc portion QCa and a central axis of the frustoconical portion QCb are substantially coincident with each other. The central axis of the frustoconical portion QCb and a central axis of one of the cylindrical portions CL leading to the frustoconical portion QCb are substantially coincident with each other. The bottom surface of the frustoconical portion QCb has a greater diameter than that of the cylindrical portion CL. The disc portion QCa has a greater diameter than that of the bottom surface of the frustoconical portion QCb. The protruding structure QC (FIG. 29) including the disc portion QCa and the frustoconical portion QCb can easily be formed when a manufacturing method using the laminated ceramic technology is used. An example of this manufacturing method will be briefly described below.

A single green sheet to be a portion included in the layer LD1 and the layer LQ (FIG. 29) of the insulator substrate 100 is prepared. A through hole corresponding to the through hole HL1 (FIG. 28) is formed in this green sheet. This through hole of the green sheet is filled with a magnetic substance paste to be a material for the magnetic substance portion 301. A magnetic-material-filled portion is formed in the through hole of the green sheet by this filling. A through hole smaller than the through hole of the green sheet is formed in the magnetic-material-filled portion. The through hole of the magnetic-material-filled portion has substantially the same diameter as that of the cylindrical portion CL when firing shrinkage is ignored.

The aforementioned through hole of the magnetic-material-filled portion is filled with a conductor paste to be a material for the conductor portion 201Q in a paste printing step. In this printing step, the conductor paste is not only loaded into the through hole of the magnetic-material-filled portion but also is applied to a portion around the through hole over an upper surface of the magnetic-material-filled portion. A degree of application of the conductor paste to the portion around the through hole can easily be adjusted according to, for example, a size of a printing pattern.

While a portion to be the magnetic substance portion 301 and the conductor portion 201Q has only been described above, the same applies to a portion to be the magnetic substance portion 302 and the conductor portion 202Q.

Green sheets to be the layer LD1 and the layer LQ are formed in the aforementioned steps. A green sheet to be a portion including the layer LD2 is formed through steps similar to these steps. Green sheets to be other portions may further be formed. For example, a total of seven green sheets are formed in a structure illustrated in FIG. 28. These green sheets are stacked to form a stack. The stack is fired to obtain a fired body including the insulator substrate 100, the magnetic substance portion 301, the magnetic substance portion 302, the conductor portion 201Q, and the conductor portion 202Q illustrated in FIG. 28. An electrode paste is printed onto this fired body, and the electrode paste is fired to form terminals (specifically, the electrode portion 401, the electrode portion 402, and the interconnector 450). The core substrate 605 is thereby obtained.

A portion of the conductor paste loaded into the through hole of the magnetic-material-filled portion in the aforementioned manufacturing method becomes the cylindrical portion CL. A portion of the conductor paste applied to the portion around the through hole over the upper surface of the magnetic-material-filled portion becomes the disc portion QCa. The frustoconical portion QCb is formed near a portion in which the cylindrical portion CL and the disc portion QCa are connected to each other, as a result of matching various conditions in the aforementioned manufacturing method. The diameter of the disc portion QCa can easily be adjusted by adjusting the size of the printing pattern of the conductor paste as described above. In other words, the width dimension WQ (FIG. 29) of the protruding structure QC can easily be adjusted.

As illustrated in the cross-sectional view in FIG. 28, the protruding structure QC of the conductor portion 201Q and the protruding structure QC of the conductor portion 202Q may face each other in the in-plane direction. As illustrated in FIG. 29, the protruding structure QC in one direction (to the right in FIG. 29) along the in-plane direction and the protruding structure QC in the other direction (to the left in FIG. 29) along the in-plane direction may be arranged in a common position in the thickness direction (vertical direction in FIG. 29).

The other structure of the core substrate 605 is substantially the same as the aforementioned structure of the core substrate 601 (FIG. 5: Embodiment 1), so that the same or corresponding components bear the same reference signs, and description thereof is not repeated.

According to Embodiment 5 (FIG. 28), the mechanical bonding between each of the conductor portions 201Q and 202Q and the magnetic substance portion 300 is enhanced by the protruding structure QC. Deterioration of electrical characteristics of the core substrate 605 with temperature cycling is thereby suppressed. The electrical characteristics of the core substrate 605 can thus further be stabilized.

The aforementioned feature of the protruding structure QC of the conductor portion may be applied to the other embodiments and its modifications described herein.

### Embodiment 6

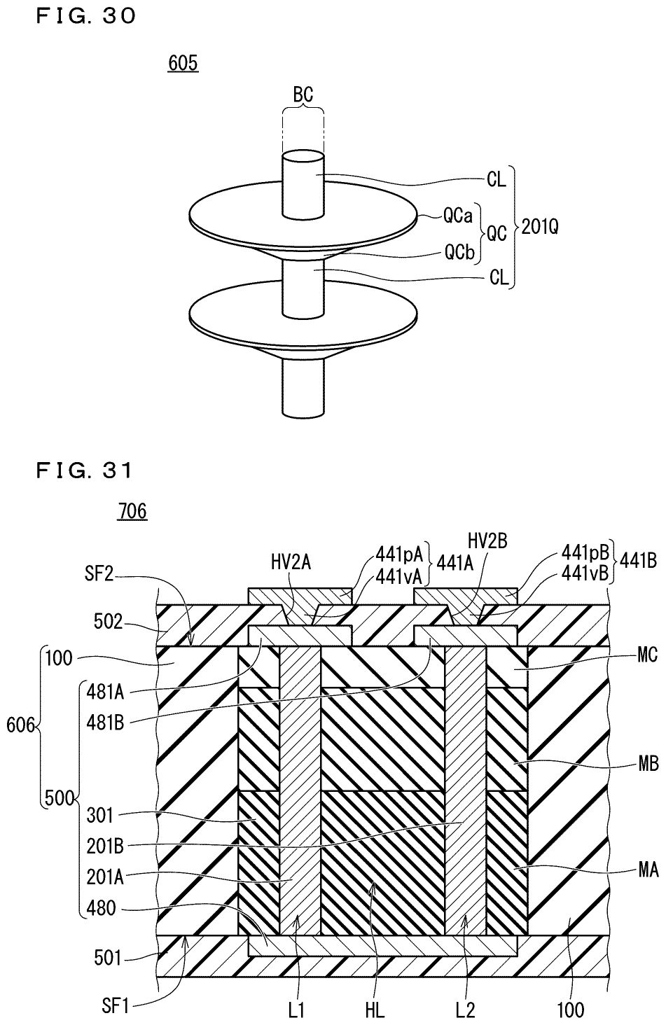

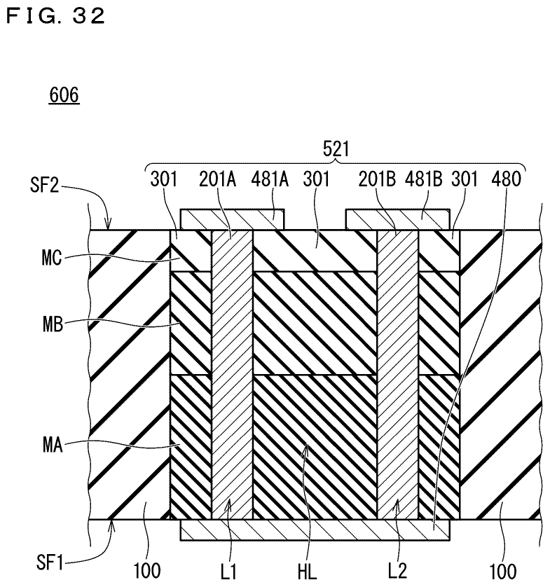

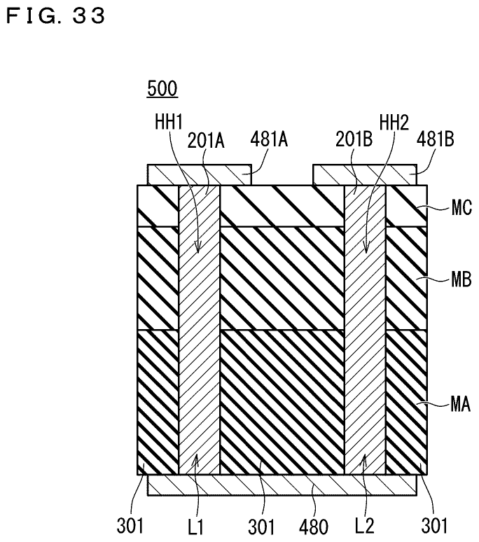

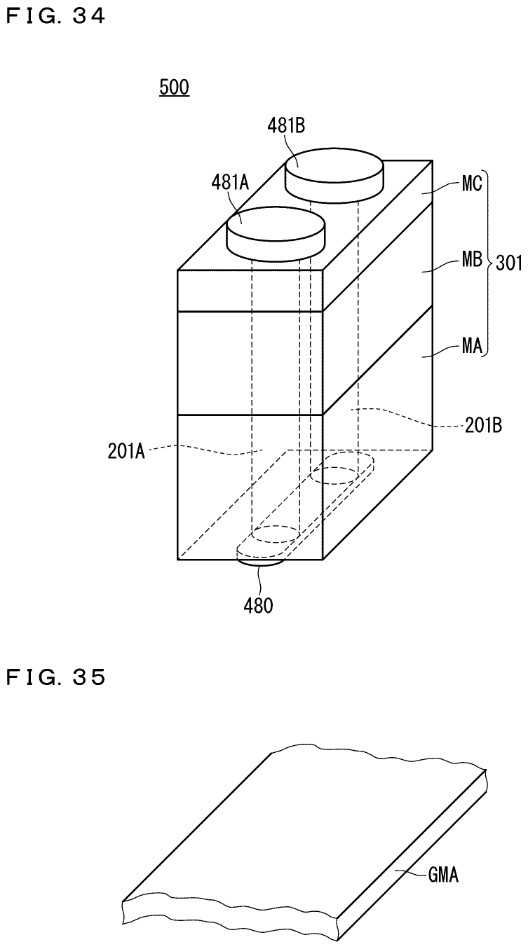

FIG. 31 is a partial cross-sectional view schematically illustrating a structure of an interposer 706 in Embodiment 6. FIG. 32 is a partial cross-sectional view schematically illustrating a structure of a core substrate 606 of the interposer 706 (FIG. 31). FIG. 33 and FIG. 34 are a cross-sectional view and a perspective view, respectively, schematically illustrating a structure of an inductor chip 500 included in the core substrate 606 (FIG. 32).

The interposer 706 has a similar application to that of the interposer 700 (FIGS. 1 and 2) described above. In other words, the interposer 706 is for mounting thereto the semiconductor element 811 (FIGS. 1 and 2), and the inductor chip 500 including the inductors L1 and L2 is built in the core substrate 606 of the interposer 706. The inductor chip may include not limited to two but three or more inductors.

The interposer 706 includes the core substrate 606 corresponding to the core substrate 601 (FIGS. 1 and 2), a component group corresponding to the wiring layer 791 (FIGS. 1 and 2), and a component group corresponding to the wiring layer 792 (FIGS. 1 and 2). The component group corresponding to the wiring layer 791 (FIGS. 1 and 2) includes an insulator layer 502, a wiring portion 441A, and a wiring portion 441B. The component group corresponding to the wiring layer 792 (FIGS. 1 and 2) includes an insulator layer 501. Not limited to the components illustrated in FIG. 31, but additional components may be added to the component groups corresponding to the wiring layer 791 and the wiring layer 792 (FIGS. 1 and 2) as appropriate according to the structure of the electronic equipment 901 (FIG. 1) or the electronic equipment 902 (FIG. 2). The components may be added by build-up or sputtering, or by bonding other components, for example.

The core substrate 606 includes the insulator substrate 100 and the inductor chip 500. The inductor chip 500 includes conductor portions 201A and 201B, and the magnetic substance portion 301. The magnetic substance portion 301 includes a plurality of magnetic substance segments (specifically, the magnetic substance segments MA to MC), similarly to Embodiment 1 described above. The dimensions of the magnetic substance portion 301 are, for example, approximately 1 mm in thickness (a dimension in the vertical direction in FIGS. 33 and 34), approximately 0.7 mm in length (a dimension in the horizontal direction in FIG. 33), and approximately 0.4 mm in width (a dimension in the horizontal direction in FIG. 34). The inductor chip 500 may include intermediate terminals 481A and 481B, and a connector 480. The core substrate 606 may be manufactured by inserting the inductor chip 500 (FIG. 33) into the through hole HL (FIG. 32) of the insulator substrate 100. The insulator substrate 100 and the inductor chip 500 may be fixed together through an adhesive (not illustrated).

The structures of the inductors L1 and L2 included in the inductor chip 500 are identical to the structures of the inductors L1 and L2 (FIG. 5) in Embodiment 1. Although the magnetic substance portion 301 for the inductor L1 and the magnetic substance portion 302 for the inductor L2 are separately provided in FIG. 5 (Embodiment 1), the magnetic substance portion for the inductor L1 and the magnetic substance portion for the inductor L2 are integrated into one common magnetic substance portion 301 in Embodiment 6 (FIG. 33). In other words, the magnetic substance portion for the inductor L1 and the magnetic substance portion for the inductor L2 are connected to each other in the direction perpendicular to the thickness direction in Embodiment 6. This can simplify a structure of the magnetic substance portion for the plurality of inductors L1 and L2. A method of manufacturing the core substrate illustrated in FIGS. 9 to 17 (Embodiment 1) may be modified such that the through holes HL1 and HL2 are integrated into the through hole HL. In such a case, the core substrate with the same structure as that of the inductors L1 and L2 in the inductor chip 500 can be obtained by the manufacturing method described in Embodiment 1.

The insulator substrate 100 may be made of any of an organic material, an inorganic material, or a mixed material thereof, and is a resin substrate or a ceramic substrate, for example. The insulator substrate 100 may thus contain the organic material. The insulator substrate 100 has the first surface SF1, and the second surface SF2 opposite the first surface SF1 in a thickness direction. Furthermore, the insulator substrate 100 includes the through hole HL between the first surface SF1 and the second surface SF2.

Each of the conductor portion 201A and the conductor portion 201B may be a non-hollow body. In other words, each of the conductor portion 201A and the conductor portion 201B need not have a hollow interior. Electrical resistance of the conductor portions 201A and 201B can thereby be reduced. Since a material for the conductor portions 201A and 201B may be the same material for the conductor portions 200 described in Embodiment 1, the description thereof will be omitted.

The conductor portions 201A and 201B extend through the through hole HH1 and the through hole HH2 (FIG. 33), respectively, in the magnetic substance portion 301. Since the through hole HL (FIG. 32) of the insulator substrate 100 includes the through holes HH1 and HH2, it can be said that the conductor portions 201A and 201B extend through the through hole HL in the core substrate 606 (FIG. 32). In other words, the magnetic substance portion 301 surrounds each of the conductor portions 201A and 201B in the through hole HL.

The magnetic substance portion 301 and the conductor portion 201A compose the inductor L1 (FIG. 4), and the magnetic substance portion 301 and the conductor portion 201B compose the inductor L2 (FIG. 4). The magnetic substance portion 301 is inorganically bonded to each of the conductor portion 201A and the conductor portion 201B. In other words, an inorganic material for each of the conductor portions 201A and 201B and an inorganic material for the magnetic substance portion 301 are bonded together without an organic material between them, and, specifically, are sintered together. Since a material for the magnetic substance portion 301 according to Embodiment 6 may be the same material for the magnetic substance portion 300 described in Embodiment 1, the description thereof will be omitted.

The conductor portion 201A may approximately linearly extend along the thickness direction. Specifically, the conductor portion 201A may extend along the thickness direction so as not to deviate from a straight line along the thickness direction as a virtual axis. In other words, the conductor portion 201A may have a virtual axis extending through the conductor portion 201A in the whole range where the conductor portion 201A is disposed in the thickness direction; the virtual axis is a straight line along the thickness direction. The conductor portion 201B may have the characteristics on extension of this conductor portion 201A.

The intermediate terminal 481A and the intermediate terminal 481B contain sintered metal as a main component, and may contain a small amount of glass component in addition to the sintered metal. The sintered metal contains Ag, AgPd, or Cu as a main component, for example. The intermediate terminal 481A faces each of the conductor portion 201A and the magnetic substance portion 301 in the thickness direction, and is inorganically bonded to each of the conductor portion 201A and the magnetic substance portion 301. Similarly, the intermediate terminal 481B faces each of the conductor portion 201B and the magnetic substance portion 301 in the thickness direction, and is inorganically bonded to each of the conductor portion 201B and the magnetic substance portion 301.

The connector 480 electrically connects the conductor portion 201A and the conductor portion 201B on the first surface SF1 of the insulator substrate 100. This provides a series connection between the inductor L1 and the inductor L2 (see the circuit diagram of FIG. 4). A material for the connector 480 may be identical to a material for the intermediate terminal 481A and the intermediate terminal 481B.

The wiring portion 441A and the wiring portion 441B may be plating layers. The wiring portion 441A includes a wiring pattern 441pA and a connecting via 441vA. A planar layout of the wiring pattern 441pA may be designed according to an application of the interposer 706. Similarly, the wiring portion 441B includes a wiring pattern 441pB and a connecting via 441vB. A planar layout of the wiring pattern 441pB may be designed according to an application of the interposer 706.

The connecting via 441vA has a bottom surface electrically connected to the conductor portion 201A. In Embodiment 6, the connecting via 441vA is connected to the conductor portion 201A through the intermediate terminal 481A. To obtain this connection, the bottom surface of the connecting via 441vA is directly connected to the intermediate terminal 481A. Similarly, the connecting via 441vB has a bottom surface electrically connected to the conductor portion 201B. In Embodiment 6, the connecting via 441vB is connected to the conductor portion 201B through the intermediate terminal 481B. To obtain this connection, the bottom surface of the connecting via 441vB is directly connected to the intermediate terminal 481B.

Each of the connecting via 441vA and the connecting via 441vB is spaced apart from the magnetic substance portion 301. Thus, the bottom surface of each of the connecting via 441vA and the connecting via 441vB is spaced apart from the magnetic substance portion 301. Furthermore, each of the connecting via 441vA and the connecting via 441vB is spaced apart from the insulator substrate 100. Thus, the bottom surface of each of the connecting via 441vA and the connecting via 441vB is spaced apart from the insulator substrate 100.

The insulator layer 502 has a via hole HV2A and a via hole HV2B in which the connecting via 441vA and the connecting via 441vB are respectively arranged. The insulator layer 502 may separate the magnetic substance portion 301 from the wiring portion 441A and the wiring portion 441B. Furthermore, the insulator layer 502 may separate the insulator substrate 100 from the wiring portion 441A and the wiring portion 441B. The insulator layer 502 has the via hole HV2A and the via hole HV2B to respectively expose the intermediate terminal 481A and the intermediate terminal 481B, but may cover the intermediate terminal 481A and the intermediate terminal 481B locally around the via hole HV2A and the via hole HV2B, respectively. The via hole HV2A and the via hole HV2B may be tapered toward the conductor portion 201A and the conductor portion 201B, respectively (downward in FIG. 31). The insulator layer 502 contains an organic material, and is an epoxy-based component, for example.

The insulator layer 501 covers the connector 480 in Embodiment 6. A material for the insulator layer 501 may be identical to a material for the insulator layer 502.

The wiring portion 441A, the wiring portion 441B, the insulator layer 502, and the insulator layer 501 are formed on the core substrate 606 (FIG. 32) by build-up method, for example, to obtain the interposer 706 (FIG. 31). The wiring portions 441A and 441B may be plating layers. In this case, the wiring portions 441A and 441B and the insulator layer 502 may be formed by a semi-additive method, and may generally be formed as described below, for example. An organic insulating film as the insulator layer 502 not having the via holes HV2A and HV2B yet is attached to the second surface SF2 of the core substrate 606. Next, the via holes HV2A and HV2B are formed by laser processing. Next, a seed layer is formed on a surface of the insulator layer 502 including an inner surface of each of the via holes HV2A and HV2B by electroless copper plating. Next, a plating resist is formed on the insulator layer 502. The plating resist exposes regions in which the wiring patterns 441pA and 441pB of the wiring portions 441A and 441B, respectively, are to be formed. Next, electrolytic copper plating is performed using the seed layer and the plating resist described above. Next, the plating resist is stripped. The wiring portions 441A and 441B are thereby formed.

Next, an example method which can manufacture a plurality of inductor chips 500 (FIGS. 33 and 34) in one batch will be described with reference to FIGS. 35 to 41.

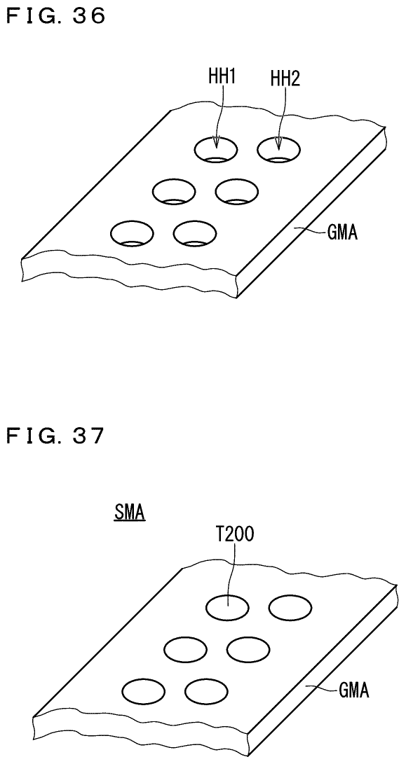

A green sheet GMA (FIG. 35) to be the magnetic substance segment MA (FIG. 33) through firing is prepared. The through holes HH1 and HH2 (FIG. 36) are formed on the green sheet GMA by, for example, laser processing. The planar shape of each of the through holes HH1 and HH2 is, for example, a circular shape of approximately 0.1 mm in diameter. The through holes HH1 and HH2 are filled with the conductor paste portions T200 (FIG. 37) to be the conductor portions 201A and 201B, respectively, through firing, which results in a sheet SMA (FIG. 37). This filling is performed by, for example, printing a conductor paste.

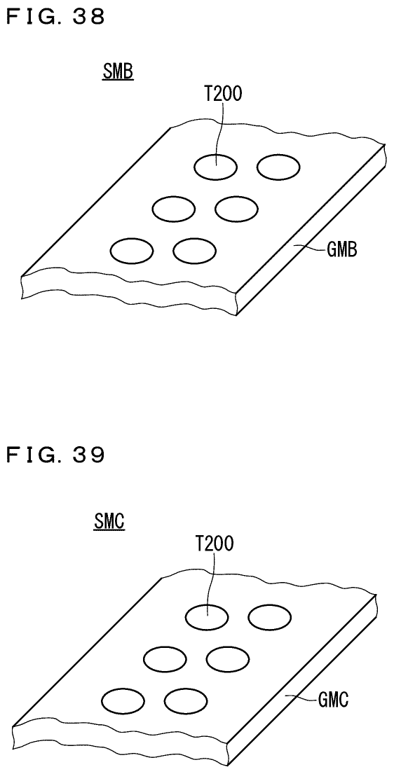

A sheet SMB (FIG. 38) including, in place of the green sheet GMA, a green sheet GMB to be the magnetic substance segment MB (FIG. 33) through firing is formed according to the same method described above. Furthermore, a sheet SMC (FIG. 39) including, in place of the green sheet GMA, a green sheet GMC to be the magnetic substance segment MC (FIG. 33) through firing is formed.

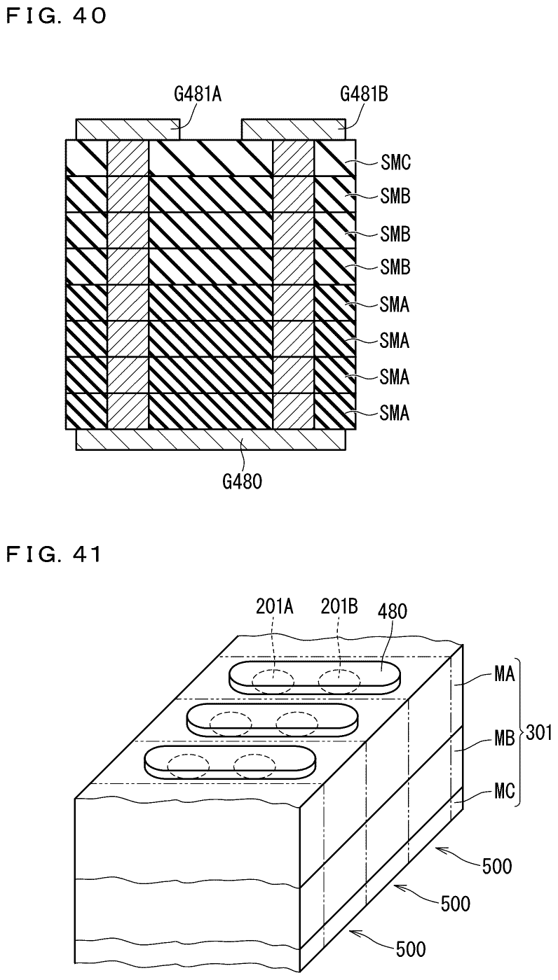

Stacking at least one sheet SMA, at least one sheet SMB, and at least one sheet SMC forms a stack (FIG. 40). In the example illustrated in FIG. 40, four sheets SMA, three sheets SMB, and one sheet SMC are stacked. Adjusting the number of sheets can adjust the thickness of each of the magnetic substance segments MA to MC. Next, firing allows an electrode paste portion G481A, an electrode paste portion G481B, and an electrode paste portion G480 to be the intermediate terminal 481A, the intermediate terminal 481B, and the connector 480, respectively, to be printed onto this stack. The thickness of each of the electrode paste portions is, for example, 20 μm. Then, these electrode paste portions and the stack are co-fired. This forms a fired body (FIG. 41) with a structure in which the plurality of inductor chips 500 are coupled to each other. The plurality of inductor chips 500 are cut out by cutting this fired body along chain double-dashed lines (FIG. 41). The plurality of inductor chips 500 are thereby obtained.

While what is previously described is a method of co-firing the electrode paste portions G481A, G481B, and G480 with the stack of the sheets SMA to SMC in the aforementioned manufacturing method, the electrode paste portions G481A, G481B, and G480 may be fired after being formed on a stack already fired, as a modification.

Embodiments 1 to 6 and its modifications may freely be combined with each other unless they are technically contradictory. While the present invention has been described in detail, the foregoing description is in all aspects illustrative and not restrictive. It is understood that numerous unillustrated modifications can be devised without departing from the scope of the present invention.

What is claimed is:

1. An inductor, comprising:
a conductor portion made of a sintered material containing sintered metal; and
a magnetic substance portion made of ceramics and including a plurality of magnetic substance segments disposed at different positions in one direction, each of the plurality of magnetic substance segments being penetrated by the conductor portion and inorganically bonded to the conductor portion, the plurality of magnetic substance segments including:
at least one first magnetic substance segment made of a first magnetic material with a permeability having a peak at a first frequency; and
at least one second magnetic substance segment made of a second magnetic material with a permeability having a peak at a second frequency different from the first frequency.

2. The inductor according to claim 1,
wherein the at least one first magnetic substance segment and the at least one second magnetic substance segment are separated by a non-magnetic material in the one direction.

3. The inductor according to claim 1,
wherein each of the at least one first magnetic substance segment and the at least one second magnetic substance segment is one magnetic substance segment.

4. The inductor according to claim 1,
wherein the at least one first magnetic substance segment comprises two magnetic substance segments separated by the at least one second magnetic substance segment.

5. A core substrate, comprising:
the inductor according to claims 1; and
an insulator substrate with a through hole in which the inductor is disposed.

6. An interposer on which a semiconductor element is to be mounted, the interposer comprising:
the core substrate according to claims 5; and
a wiring layer stacked on the core substrate.
